(19) United States
(12) Patent Application Publication
(10) Pub. No.: US 2026/0040817 A1
(43) Pub. Date: Feb. 5, 2026

(54) Light-Emitting Device, Display Panel, and Display Apparatus

(71) Applicant: BOE TECHNOLOGY GROUP CO., LTD., Chaoyang District, Beijing (CN)

(72) Inventors: Yuqian Sun, Beijing (CN); Lei Chen, Beijing (CN); Xueqin Chen, Beijing (CN)

(21) Appl. No.: 18/995,347

(22) PCT Filed: May 31, 2024
(86) PCT No.: PCT/CN2024/096723

§ 371 Date: Jan. 16, 2025

(30) Foreign Application Priority Data
Jun. 9, 2023 (CN) 202310686726.4

(51) Int. Cl. H10K 85/60; G09G 3/3233; H10K 50/15; H10K 50/18

(52) U.S. Cl. CPC H10K 85/636; G09G 3/3233; H10K 85/631; H10K 85/633; G09G 2320/043; H10K 50/15; H10K 50/181; H10K 85/615; H10K 85/622; H10K 85/626; H10K 85/6572; H10K 85/6574; H10K 85/6576

(57) ABSTRACT

A light-emitting device includes a cathode and an anode that are oppositely arranged, and at least two light-emitting units disposed between the cathode and the anode. The at least two light-emitting units are arranged in sequence. At least one light-emitting unit of the at least two light-emitting units includes a light-emitting layer and a first-type functional layer disposed on a side of the light-emitting layer. The first-type functional layer includes an auxiliary functional layer, a material of the auxiliary functional layer includes a first functional material, and the first functional material is selected from any one of structures represented by a general formula (I).

### CROSS-REFERENCE TO RELATED APPLICATIONS

This application is the United States national phase of International Patent Application No. PCT/CN2024/096723, filed May 31, 2024, and claims priority to Chinese Patent Application No. 202310686726.4, filed Jun. 9, 2023, the disclosures of which are hereby incorporated by reference in their entireties.

### BACKGROUND OF THE INVENTION

### Field of the Invention

The present disclosure relates to the field of display technologies, and in particular, to a light-emitting device, a display panel and a display apparatus.

### Description of Related Art

Organic light-emitting diode (OLED) light-emitting device has become the most promising new-type light-emitting device in recent years due to advantages such as self-luminous and fast response. In a light emission process of the OLED light-emitting device, holes from an anode and electrons from a cathode are transmitted to a light-emitting layer included in the OLED light-emitting device, these electrons and holes are combined to form electron-hole pairs, and the formed electron-hole pairs are converted from a singlet state to a ground state to emit light.

### SUMMARY OF THE INVENTION

In an aspect, a light-emitting device is provided. The light-emitting device includes a cathode and an anode that are oppositely arranged, and at least two light-emitting units disposed between the cathode and the anode; the at least two light-emitting units are arranged in sequence; at least one light-emitting unit of the at least two light-emitting units includes: a light-emitting layer and a first-type functional layer disposed on a side of the light-emitting layer; the first-type functional layer includes an auxiliary functional layer, a material of the auxiliary functional layer includes a first functional material, and the first functional material is selected from any one of structures represented by a following general formula (I).

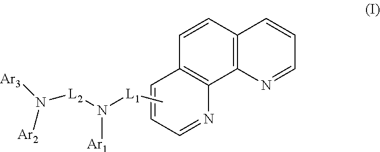

In the general formula (I), L₁ is selected from any one of single bond, substituted or unsubstituted C6-C39 arylene, and substituted or unsubstituted C6-C39 heteroarylene, L₂ is selected from any one of substituted or unsubstituted C6-C39 arylene and substituted or unsubstituted C6-C39 heteroarylene, and Ar₁, Ar₂ and Ar₃ are same or different and are independently selected from any one of substituted or unsubstituted C6-C39 aryl, substituted or unsubstituted C5-C60 heteroaryl, substituted or unsubstituted C6-C60 aryloxy, substituted or unsubstituted C6-C39 arylamine, substituted or unsubstituted C6-C39 arylboryl, substituted or unsubstituted C6-C39 arylphosphino, and substituted or unsubstituted C6-C39 arylsilyl.

In some embodiments, the first-type functional layer is located on a side of the light-emitting layer proximate to the anode; and the auxiliary functional layer is configured to block electrons.

In some embodiments, the first-type functional layer further includes an electron blocking layer stacked with the auxiliary functional layer, a material of the electron blocking layer includes a second functional material, and the second functional material is selected from any one of structures represented by a following general formula (II).

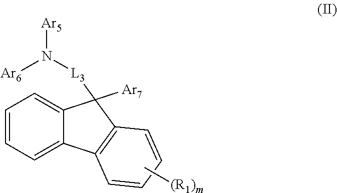

In the general formula (II), L₃ is selected from any one of single bond, substituted or unsubstituted C3-C30 arylene, and substituted or unsubstituted C3-C30 heteroarylene, Ar₅ and Ar₆ are same or different and are independently selected from any one of substituted or unsubstituted C6-C39 aryl, substituted or unsubstituted C5-C60 heteroaryl, substituted or unsubstituted C6-C60 aryloxy, substituted or unsubstituted C6-C39 arylamine, substituted or unsubstituted C6-C39 arylboryl, substituted or unsubstituted C6-C39 arylphosphino, and substituted or unsubstituted C6-C39 arylsilyl, Ar₇ and R₁ are same or different and are independently selected from any one of hydrogen, deuterium, substituted or unsubstituted C1-C39 alkyl, substituted or unsubstituted C2-C39 alkenyl, substituted or unsubstituted C2-C39 alkynyl, substituted or unsubstituted C6-C39 aryl, substituted or unsubstituted C5-C60 heteroaryl, substituted or unsubstituted C6-C60 aryloxy, substituted or unsubstituted C1-C39 alkoxy, substituted or unsubstituted C6-C39 arylamine, substituted or unsubstituted C3-C39 cycloalkyl, substituted or unsubstituted C3-C39 heterocycloalkyl, substituted or unsubstituted C1-C39 alkylsilyl, substituted or unsubstituted C1-C39 alkylboryl, substituted or unsubstituted C6-C39 arylboryl, substituted or unsubstituted C6-C39 arylphosphino, and substituted or unsubstituted C6-C39 arylsilyl, and m is a positive integer greater than or equal to 1.

In some embodiments, the electron blocking layer is located on a side of the auxiliary functional layer away from the light-emitting layer and configured to block electrons.

In some embodiments, the first-type functional layer further includes a hole transport layer stacked with the electron blocking layer, a material of the hole transport layer includes a third functional material, and the third functional material is selected from any one of structures represented by a following general formula (III).

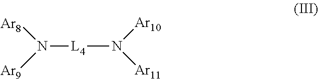

In the general formula (III), L₄ is selected from any one of substituted or unsubstituted C3-C30 arylene and substituted or unsubstituted C3-C30 heteroarylene, and Ar₈, Ar₉, Ar₁₀ and Ar₁₁ are same or different and are independently selected from any one of substituted or unsubstituted C6-C39 aryl, substituted or unsubstituted C5-C60 heteroaryl, substituted or unsubstituted C6-C60 aryloxy, substituted or unsubstituted C1-C39 alkoxy, substituted or unsubstituted C6-C39 arylamine, and substituted or unsubstituted C6-C39 arylsilyl.

In some embodiments, the hole transport layer is located on a side of the electron blocking layer away from the light-emitting layer and configured to transport holes.

In some embodiments, the first functional material is selected from any one of structures represented by a following general formula (IV).

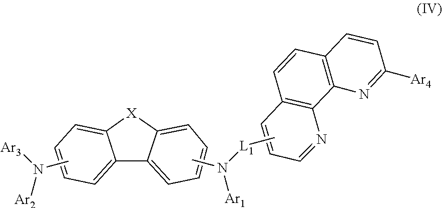

In the general formula (IV), X is selected from any one of O, S, N(R₂), and C(R₃R₄), and R₂, R₃, R₄ and Ar₄ are same or different and are independently selected from any one of hydrogen, deuterium, substituted or unsubstituted C1-C39 alkyl, substituted or unsubstituted C2-C39 alkenyl, substituted or unsubstituted C2-C39 alkynyl, substituted or unsubstituted C6-C39 aryl, substituted or unsubstituted C5-C60 heteroaryl, substituted or unsubstituted C6-C60 aryloxy, substituted or unsubstituted C1-C39 alkoxy, substituted or unsubstituted C6-C39 arylamine, substituted or unsubstituted C3-C39 cycloalkyl, substituted or unsubstituted C3-C39 heterocycloalkyl, substituted or unsubstituted C1-C39 alkylsilyl, substituted or unsubstituted C1-C39 alkylboryl, substituted or unsubstituted C6-C39 arylboryl, substituted or unsubstituted C6-C39 arylphosphino, and substituted or unsubstituted C6-C39 arylsilyl.

In some embodiments, in a case where the first functional material is selected from the structures represented by the general formula (I), the structures represented by the general formula (I) each contains at least one deuterium atom; or in a case where the first functional material is selected from structures represented by the general formula (IV), the structures represented by the general formula (IV) each contains at least one deuterium atom.

In some embodiments, at least one of Ar₅, Ar₆, Ar₇, L₃, and R₁ contains a deuterium atom.

In some embodiments, at least one of Ar₈, Ar₉, Ar₁₀, Ar₁₁, and L₄ contains a deuterium atom.

In some embodiments, at least one of Ar₈, Ar₉, Ar₁₀ and Ar₁₁ is different from a rest of Ar₈, Ar₉, Ar₁₀ and Ar₁₁.

In some embodiments, a first ionization potential of the first functional material is greater than or equal to a first ionization potential of the second functional material; and the first ionization potential of the second functional material is greater than or equal to a first ionization potential of the third functional material.

In some embodiments, a difference between the first ionization potential of the first functional material and the first ionization potential of the second functional material is less than or equal to 0.2 eV.

In some embodiments, a difference between the first ionization potential of the second functional material and the first ionization potential of the third functional material is less than or equal to 0.2 eV.

In some embodiments, a difference between the first ionization potential of the first functional material and the first ionization potential of the third functional material is less than or equal to 0.3 eV.

In some embodiments, a thickness of the electron blocking layer is greater than a thickness of the auxiliary functional layer.

In some embodiments, a thickness of the auxiliary functional layer is in a range of 5 nm to 50 nm, inclusive.

In some embodiments, a thickness of the electron blocking layer is in a range of 10 nm to 55 nm, inclusive.

In some embodiments, a thickness of the hole transport layer is in a range of 50 nm to 200 nm, inclusive.

In some embodiments, the light-emitting device further includes a charge generating layer located between two adjacent light-emitting units of the at least two light-emitting units; the charge generating layer includes an electron generating layer and a hole generating layer that are stacked; and a material of the hole generating layer includes the third functional material.

In some embodiments, the first-type functional layer further includes a hole injection layer, and the hole injection layer is located on a side of the hole transport layer away from the electron blocking layer; and a material of the hole injection layer includes the third functional material.

In some embodiments, the at least one light-emitting unit further includes a second-type functional layer, and the second-type functional layer is located on a side of the light-emitting layer away from the first-type functional layer and configured to transport electrons.

In some embodiments, a light-emitting layer of each light-emitting unit of the at least two light-emitting units is configured to emit green light.

In another aspect, a display panel is provided. The display panel includes light-emitting devices each according to any one of the above embodiments and driving circuits. The driving circuits are configured to drive the light-emitting devices to emit light.

In some embodiments, a display apparatus is provided. The display apparatus includes the display panel according to any one of the above embodiments and a driver chip. The driver chip is configured to drive the display panel to display images.

### BRIEF DESCRIPTION OF THE DRAWINGS

In order to describe the technical solutions in the present disclosure more clearly, the accompanying drawings to be used in some embodiments of the present disclosure will be briefly introduced below. Obviously, the accompanying drawings to be described below are merely drawings of some embodiments of the present disclosure, and a person of ordinary skill in the art can obtain other drawings according to those drawings. In addition, the accompanying drawings in the following description may be regarded as schematic diagrams, but are not limitations on actual sizes of products, actual processes of methods and actual timings of signals involved in the embodiments of the present disclosure.

FIG. 1 is a structural diagram of a display apparatus, in accordance with some embodiments;

FIG. 2 is a structural diagram of a display panel, in accordance with some embodiments;

FIG. 3 is a structural diagram of another display panel, in accordance with some embodiments;

FIG. 4 is a structural diagram of a light-emitting device, in accordance with some embodiments;

FIG. 5 is a structural diagram of another light-emitting device, in accordance with some embodiments;

FIG. 6 is a diagram showing an orbital distribution of a first functional material, in accordance with some embodiments;

FIG. 7 is a diagram showing an orbital distribution of another first functional material, in accordance with some embodiments;

FIG. 8 is a structural diagram of another light-emitting device, in accordance with still some embodiments; and

FIG. 9 is a structural diagram of a device under test 30, in accordance with some embodiments.

### DESCRIPTION OF THE INVENTION

The technical solutions in some embodiments of the present disclosure will be clearly and completely described below in conjunction with the accompanying drawings. Obviously, the embodiments to be described are merely some but not all embodiments of the present disclosure. All other embodiments obtained by a person of ordinary skill in the art based on the embodiments of the present disclosure should fall within the protection scope of the present disclosure.

Unless the context requires otherwise, throughout the specification and the claims, the term “comprise” and other forms thereof such as the third-person singular form “comprises” and the present participle form “comprising” are construed as an open and inclusive meaning, i.e., “including, but not limited to”. In the description of the specification, the term such as “one embodiment”, “some embodiments”, “exemplary embodiments”, “an example”, “a specific example” or “some examples” is intended to indicate that specific features, structures, materials or characteristics related to the embodiment(s) or example(s) are included in at least one embodiment or example of the present disclosure. Schematic representations of the above terms do not necessarily refer to the same embodiment(s) or example(s). In addition, the specific features, structures, materials, or characteristics may be included in any one or more embodiments or examples in any suitable manner.

Hereinafter, the terms “first” and “second” are used for descriptive purposes only, and are not to be construed as indicating or implying the relative importance or implicitly indicating the number of indicated technical features. Thus, a feature defined with “first” or “second” may explicitly or implicitly include one or more of the features. In the description of the embodiments of the present disclosure, the term “a/the plurality of” means two or more unless otherwise specified.

The phrase “at least one of A, B and C” has the same meaning as the phrase “at least one of A, B or C”, both including following combinations of A, B and C: only A, only B, only C, a combination of A and B, a combination of A and C, a combination of B and C, and a combination of A, B and C.

The phrase “A and/or B” includes following three combinations: only A, only B, and a combination of A and B.

As used herein, the term such as “about”, “substantially” or “approximately” includes a stated value and an average value within an acceptable range of deviation of a particular value; the acceptable range of deviation may be determined, for example, by a person of ordinary skill in the art, considering measurement in question and errors (i.e., limitations of a measurement system) associated with measurement of a particular quantity.

As used herein, the term such as “parallel”, “perpendicular” or “equal” includes a stated condition and a condition similar to the stated condition within an acceptable range of deviation; the acceptable range of deviation may be determined, for example, by a person of ordinary skill in the art, considering measurement in question and errors (i.e., limitations of a measurement system) associated with measurement of a particular quantity. For example, the term “parallel” includes absolute parallelism and approximate parallelism, and an acceptable range of deviation of the approximate parallelism may be, for example, a deviation within 5°; the term “perpendicular” includes absolute perpendicularity and approximate perpendicularity, and an acceptable range of deviation of the approximate perpendicularity may also be, for example, a deviation within 5°; and the term “equal” includes absolute equality and approximate equality, and an acceptable range of deviation of the approximate equality may be, for example, that a difference between two equals is less than or equal to 5% of either of the two equals.

It will be understood that, in a case where a layer or element is referred to as being on another layer or substrate, it may be that the layer or element is directly on the another layer or substrate, or it may be that intermediate layer(s) exist between the layer or element and the another layer or substrate.

Exemplary embodiments are described herein with reference to sectional views and/or plan views as idealized exemplary drawings. In the accompanying drawings, thicknesses of layers and sizes of regions are enlarged for clarity. Thus, variations in shape with respect to the accompanying drawings due to, for example, manufacturing technologies and/or tolerances may be envisaged. Therefore, the exemplary embodiments should not be construed as being limited to the shapes of the regions shown herein, but including shape deviations due to, for example, manufacturing. For example, an etched region shown to have a rectangular shape generally has a feature of being curved. Therefore, the regions shown in the accompanying drawings are schematic in nature, and their shapes are not intended to show actual shapes of the regions in an apparatus, and are not intended to limit the scope of the exemplary embodiments.

It will be noted that, for example, a reference sign “1/2” appearing in the drawings of the present disclosure represents that a component 1 and a component 2 may both refer to a component indicated by this reference sign. For example, a reference sign “301/302” represents that a device under test 301 and a device under test 302 may both be represented by a component indicated by this reference sign. Other similar reference signs appearing in the drawings also follows the above description.

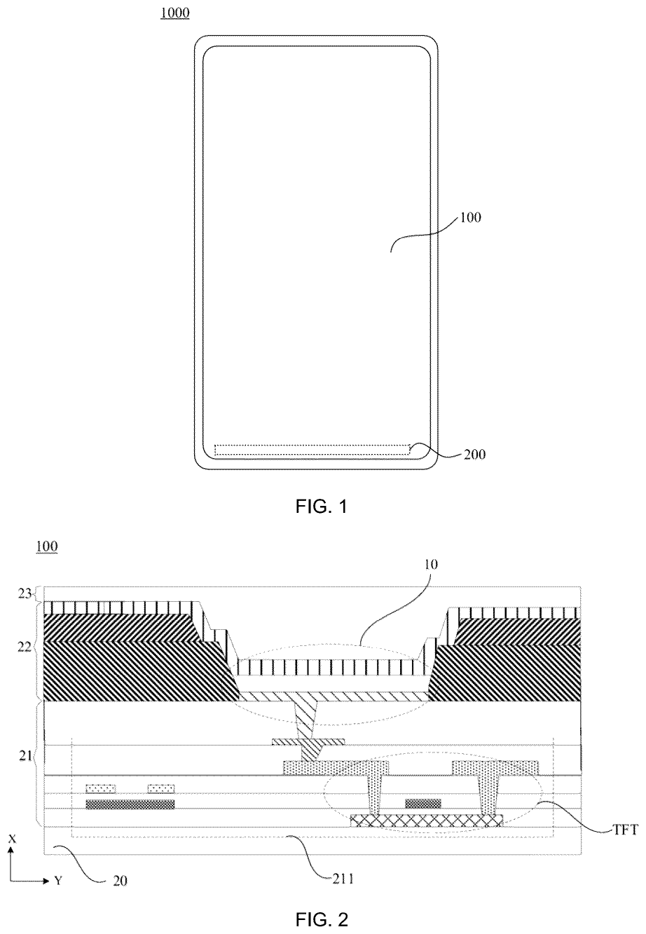

As shown in FIG. 1, some embodiments of the present disclosure provide a display apparatus 1000, and the display apparatus 1000 includes a display panel 100.

In some examples, the display apparatus 1000 may be an organic light-emitting diode (OLED) display apparatus.

For example, as shown in FIG. 1, the display apparatus 1000 further includes a driver chip 200. The driver chip 200 is used to drive the display panel 100 to display images.

In some examples, the driver chip 200 is electrically connected to the display panel 100 through a flexible circuit board and is disposed on the back of the display panel 100 as the flexible circuit board is bent, thereby narrowing the bezel of the display apparatus 1000 and increasing an area of the display region. The dotted line in FIG. 1 illustrates that the driver chip 200 is disposed on the back of the display panel 100.

In addition, the display apparatus 1000 may further include an under-screen camera and an under-screen fingerprint recognition sensor, so that the display apparatus 1000 is able to achieve various functions such as photographing, video recording, fingerprint recognition, or face recognition.

The display apparatus 1000 may be any display apparatus that displays images whether in motion (e.g., a video) or stationary (e.g., static images), and whether textual or graphical. More specifically, it is expected that the display apparatus 1000 in the embodiments may be implemented in or associated with a variety of electronic devices; the variety of electronic devices may include (but are not limit to), for example, mobile phones, wireless devices, personal data assistants (PDA), hand-held or portable computers, GPS receivers/navigators, cameras, MP4 video players, video cameras, game consoles, watches, clocks, calculators, TV monitors, flat panel displays, computer monitors, car displays (e.g., odometer displays), navigators, cockpit controllers and/or displays, camera view displays (e.g., rear view camera displays in vehicles), electronic photos, electronic billboards or indicators, projectors, building structures, packagings and aesthetic structures (e.g., a display for an image of a piece of jewelry), etc.

In some embodiments, as shown in FIG. 2, the display panel 100 includes a base substrate 20, and an array layer 21, a light-emitting function layer 22, and an encapsulation layer 23 that are stacked on the base substrate 20. The light-emitting function layer 22 is located on a side of the array layer 21. The array layer 21 includes a plurality of driving circuits 211, and a driving circuit 211 includes a plurality of transistors TFT. The light-emitting function layer 22 includes a plurality of light-emitting devices 10, and the plurality of light-emitting devices 10 are arranged in a second direction Y.

In some examples, as shown in FIG. 2, the plurality of driving circuits 211 may be coupled to the plurality of light-emitting devices 10 in a one-to-one correspondence. In some other examples, one driving circuit 211 may be coupled to multiple light-emitting devices 10, or multiple driving circuits 211 may be coupled to one light-emitting device 10.

For example, in the display panel 100, the driving circuit 211 may generate a driving current. Each light-emitting device 10 may emit light due to a driving action of the driving current generated by corresponding driving circuit(s) 211, and the light emitted by the plurality of light-emitting devices 10 cooperates with each other, so that the display panel 100 achieves a display function.

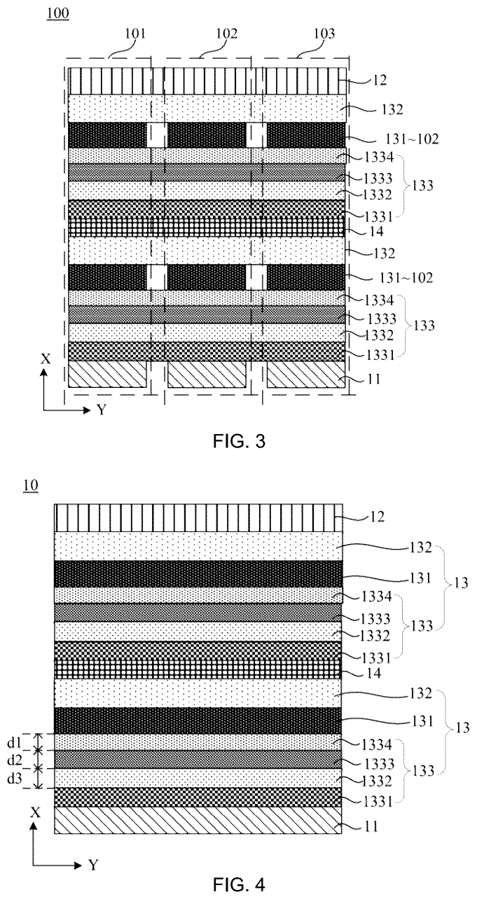

In some embodiments, as shown in FIG. 3, the plurality of light-emitting devices 10 of the display panel 100 include red light-emitting devices 101, green light-emitting devices 102 and blue light-emitting devices 103. Due to the action of driving voltages, the red light-emitting devices 101 emit red light, the green light-emitting devices 102 emit green light, and the blue light-emitting devices 103 emit blue light.

It will be noted that, FIG. 3 is a simplified schematic diagram obtained after removing other film layers in the display panel 100 except film layers related to the light-emitting devices. In FIG. 3, the multiple light-emitting devices are, for example, a red light-emitting device 101, a green light-emitting device 102 and a blue light-emitting device 103; each light-emitting device 10 includes respective light-emitting layers 131 and a respective anode 11; except for the light-emitting layers 131 and the anode 11, film layers each included in a light-emitting device are connected as a whole for sharing.

As mentioned in the background, in the field of organic semiconductors, OLED technology has attracted more and more attention from academia and industry, and has been successfully applied in commercial flat panel display and lighting industries. OLED light-emitting devices have the characteristic of self-luminous, so that OLED display panels and OLED light-emitting substrates have the advantage of not requiring a backlight source, and have the advantages of thinness and lightness. Furthermore, OLED light-emitting devices have the advantages of being all solid-state, fast response time, and wide operating temperature range. According to the number of light-emitting units in a sub-pixel, OLED light-emitting devices may be classified into single-layer light-emitting devices and tandem light-emitting devices, and the structure of the tandem light-emitting device will be introduced below.

In some embodiments, as shown in FIG. 4, the light-emitting device 10 includes an anode 11 and a cathode 12 that are arranged opposite to each other, and at least two light-emitting units 13 disposed between the cathode 12 and the anode 11; the at least two light-emitting units 13 are stacked, and each light-emitting unit 13 of the at least two light-emitting units 13 includes a light-emitting layer 131. In this case, the light-emitting device 10 is a tandem light-emitting device 10, for example, a tandem OLED light-emitting device 10.

Based on the above structure, the light emission principle of the light-emitting device 10 is described as follows. A circuit connected to the anode 11 and the cathode 12 is employed, holes are injected into the light-emitting layer 131 by the anode 11, electrons are injected into the light-emitting layer 131 by the cathode 12, the injected electrons and holes form excitons (i.e., electron-hole pairs) in the light-emitting layer 131, and the excitons transition to the ground state by radiation to emit photons. It will be appreciated that in the light emission process of the tandem OLED light-emitting device 10, none of the three processes of efficient charge generation, effective charge injection, and fast charge transfer is dispensable. The above-mentioned charge is hole or electron.

It will be understood that, firstly, since the OLED light-emitting device is driven by a current to emit light, in a case of being driven by a same current density, a luminance of a tandem OLED light-emitting device 10 including n identical light-emitting units 13 is n times a luminance of a conventional OLED light-emitting device 10 including a single light-emitting unit 13. Therefore, the current efficiency of the tandem OLED light-emitting device 10 is n times that of the conventional OLED light-emitting device 10. Secondly, an OLED display apparatus or an OLED lighting apparatus operates at a certain luminance, in a case of being at a same luminance, the current density for driving the tandem OLED light-emitting device 10 is 1/n of the current density for driving the conventional OLED light-emitting device 10. The greater the current density for driving the OLED light-emitting device 10 is, the faster the OLED light-emitting device 10 ages and the shorter the service life is, so that the service life of the tandem OLED light-emitting device 10 is extended. Therefore, the tandem OLED light-emitting device 10 plays an important role in the field of OLED display and OLED lighting.

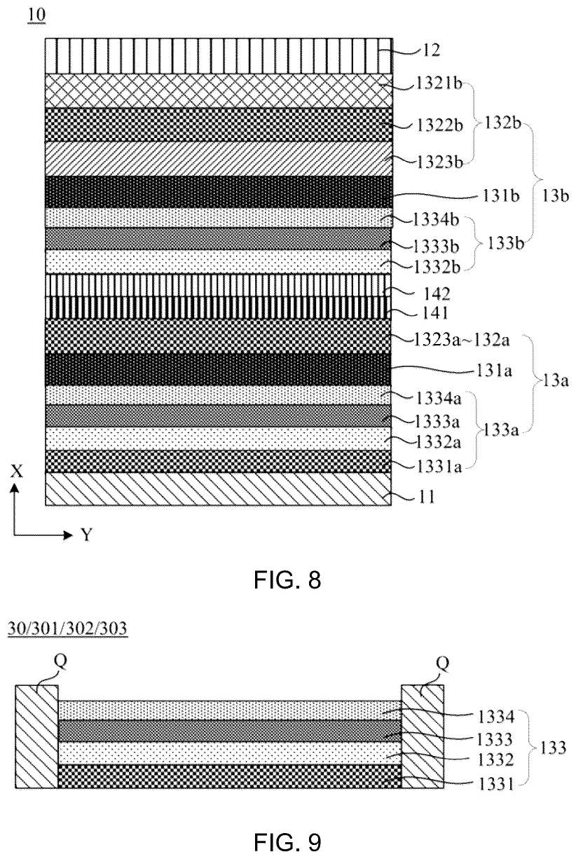

In some embodiments, as shown in FIGS. 4 and 8, the light-emitting device 10 further includes a charge generating layer 14, and the charge generating layer 14 is located between two adjacent light-emitting units 13 of the at least two light-emitting units 13; the charge generating layer 14 includes an electron generating layer 141 and a hole generating layer 142 that are stacked. The electron generating layer 141 is located on a side proximate to the anode 11; the hole generating layer 142 is located on a side proximate to the cathode 12.

A plurality of light-emitting units 13 of the tandem OLED light-emitting device 10 are sequentially connected through the charge generating layer 14 in a direction perpendicular to a light exit surface; the direction perpendicular to the light exit surface is, for example, the first direction X shown in FIG. 4. Moreover, the charge generating layer 14 not only connects the light-emitting units 13 in the tandem OLED light-emitting device 10, but also has a significant influence on the process of efficient charge (hole or electron) generation; thus, the charge generating layer 14 has a significant influence on the performance of the light-emitting device 10.

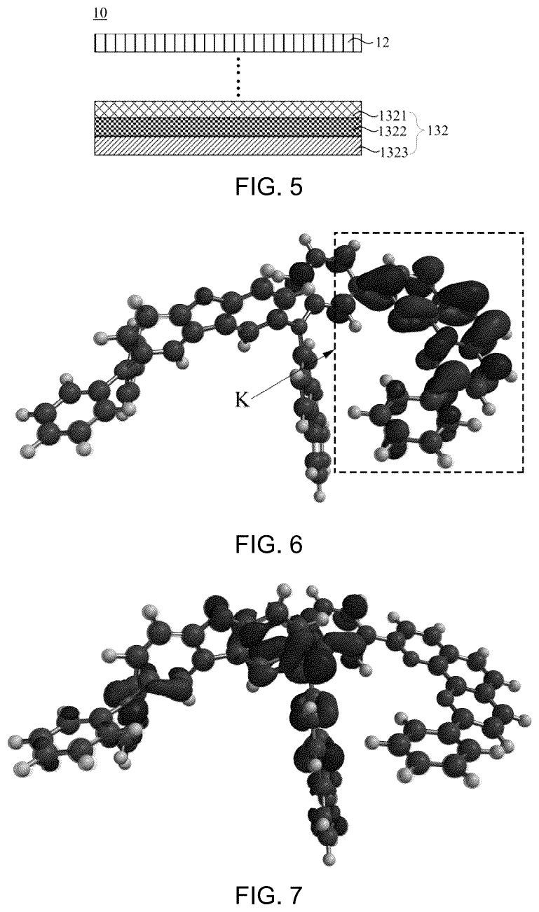

In some embodiments, as shown in FIGS. 4 and 5, each light-emitting unit 13 of the at least two light-emitting units 13 further includes a second-type functional layer 132; the second-type functional layer 132 is located on a side of the light-emitting layer 131 proximate to the cathode 12 and is configured to transport electrons or block holes, which may achieve effective electron injection and fast electron transport or block holes to facilitate the balance between electrons and holes in the light emission process.

It will be understood that, in the case where the at least two light-emitting units 13 are connected through the charge generating layer 14, the second-type functional layer 132 is located on the side of the light-emitting layer 131 proximate to the cathode 12, which means that, in a case where the light-emitting unit 13 is a light-emitting unit 13 proximate to the cathode 12 of the at least two light-emitting units 13, the second-type functional layer 132 is located between the light-emitting layer 131 and the cathode 12, and in a case where the light-emitting unit 13 is another light-emitting unit 13 of the at least two light-emitting units 13 except the light-emitting unit 13 proximate to the cathode 12, the second-type functional layer 132 is located between the light-emitting layer 131 and the charge generating layer 14.

For example, the second-type functional layer 132 includes any one or more of an electron injection layer 1321, an electron transport layer 1322, and a hole blocking layer 1323.

As shown in FIGS. 4 and 5, in the case where the second-type functional layer 132 includes the electron injection layer 1321, the electron transport layer 1322 and the hole blocking layer 1323, the electron injection layer 1321, the electron transport layer 1322 and the hole blocking layer 1323 of the second-type functional layer 132 are sequentially arranged in a direction away from the cathode 12, for example.

For example, as shown in FIG. 3, in the case where the display panel 100 includes the red light-emitting device 101, the green light-emitting device 102 and the blue light-emitting device 103, the red light-emitting device 101, the green light-emitting device 102 and the blue light-emitting device 103 may share one or more of the layers of the second-type functional layer 132.

In some embodiments, as shown in FIG. 4, each light-emitting unit 13 of the at least two light-emitting units 13 further includes a first-type functional layer 133; the first-type functional layer 133 is located on a side of the light-emitting layer 131 proximate to the anode 11 and is configured to transport holes or block electrons, which may achieve effective hole injection and fast hole transport, and may keep the electrons remain in the light-emitting layer 131 adjacent to the first-type functional layer 133 as much as possible to balance electrons and holes in the light emission process, thereby improving the light emission efficiency of the light-emitting layer 131.

It will be understood that, in the case where at least two light-emitting units 13 are connected through the charge generating layer 14, the first-type functional layer 133 is located on the side of the light-emitting layer 131 proximate to the anode 11, which refers to that, in a case where the light-emitting unit 13 is a light-emitting unit 13 proximate to the anode 11 of the at least two light-emitting units 13, the first-type functional layer 133 is located between the light-emitting layer 131 and the anode 11, and in a case where the light-emitting unit 13 is another light-emitting unit 13 of the at least two light-emitting units 13 except the light-emitting unit 13 proximate to the anode 11, the first-type functional layer 133 is located between the light-emitting layer 131 and the charge generating layer 14.

For example, as shown in FIG. 4, the first-type functional layer 133 includes any one or more of a hole injection layer 1331, a hole transport layer 1332, and an electron blocking layer 1333.

As shown in FIG. 4, in the case where the first-type functional layer 133 includes the hole injection layer 1331, the hole transport layer 1332 and the electron blocking layer 1333, the hole injection layer 1331, the hole transport layer 1332 and the electron blocking layer 1333 of the first-type functional layer 133 may be sequentially arranged in a direction away from the anode 11, for example.

For example, as shown in FIG. 3, in the case where the display panel 100 includes the red light-emitting device 101, the green light-emitting device 102 and the blue light-emitting device 103, the red light-emitting device 101, the green light-emitting device 102 and the blue light-emitting device 103 may share one or more of the layers of the first-type functional layer 133.

With the development of organic light-emitting devices 10, the stability of the light-emitting device 10 has always attracted much attention due to its direct influence on the service life of the light-emitting device 10. Moreover, the organic materials used in the light-emitting layer 131, the first-type functional layer 133, and the second-type functional layer 132 have different compositions, which have a significant influence on the stability of the organic light-emitting device 10. Therefore, an important factor affecting the service life of the light-emitting device 10 is the stability of the organic material.

In some implementations, a material of the first-type functional layer 133 is an aromatic amine material, but the aromatic amine material has poor electron stability. During the long-term use, the aromatic amine material is easily attacked by electrons and cracks, which leads to a failure of the first-type functional layer 133 so that the first-type functional layer 133 is unable to perform the function of transporting holes or blocking electrons. As a result, the service life of the light-emitting device 10 is shortened.

Based on this, some embodiments of the present disclosure provide a light-emitting device 10 in which a first-type functional layer 133 includes an auxiliary functional layer 1334; a material of the auxiliary functional layer 1334 includes a first functional material GF1, and the first functional material GF1 is selected from any one of structures represented by the following general formula (I).

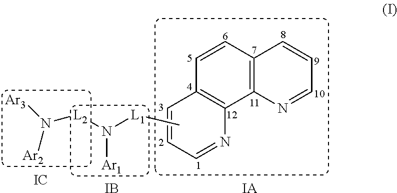

In the general formula (I), L₁ is selected from any one of single bond, substituted or unsubstituted C6-C39 arylene, and substituted or unsubstituted C6-C39 heteroarylene.

L₂ is selected from any one of substituted or unsubstituted C6-C39 arylene, and substituted or unsubstituted C6-C39 heteroarylene.

Ar₁, Ar₂ and Ar₃ are the same or different, and are independently selected from any one of substituted or unsubstituted C6-C39 aryl, substituted or unsubstituted C5-C60 heteroaryl, substituted or unsubstituted C6-C60 aryloxy, substituted or unsubstituted C6-C39 arylamine, substituted or unsubstituted C6-C39 arylboryl, substituted or unsubstituted C6-C39 arylphosphino, and substituted or unsubstituted C6-C39 arylsilyl.

In the structure represented by the general formula (I), the part IA is a phenanthroline group, and the part IB and the part IC are both triarylamine groups.

Regarding the structure represented by the general formula (I), several points need to be explained below.

L₁ may be selected from single bond, and in the case where L₁ is a single bond, the nitrogen atom of the part IB and the phenanthroline group of the part IA are directly linked by a covalent bond.

A connection between L₁ and the phenanthroline group of the part IA shown in the general formula (I) means that L₁ may be connected to any one of 1-position, 2-position, 3-position, 5-position, 6-position, 8-position, 9-position, and 10-position carbon atoms of the phenanthroline group; that is, L₁ may be linked to any carbon atom of the 1-position, 2-position, 3-position, 5-position, 6-position, 8-position, 9-position, and 10-position carbon atoms that has a substitutable position.

The term “Cx aryl” refers to aryl having x carbon (C) atoms in total, where x is a positive integer, and the same applies below. As for the understanding of the terms “Cx heteroaryl”, “Cx aryloxy” and the like, reference may be made to the above content, and details will not be repeated here.

Aryl may be phenyl or the like. Heteroaryl may be furyl, pyranyl, thienyl, pyridyl or the like.

The term “Phenyl” is a generic term for the remaining group by the removal of a hydrogen atom from a carbon atom of the benzene ring. The term “Phenylene” is a generic term for the remaining group by the removal of the hydrogen atoms from two carbon atoms of the benzene ring. As for the understanding of terms of “arylene”, “heteroarylene” and the like, reference may be made to the above content, and details will not be repeated here.

In a case where Ar₁, Ar₂ and Ar₃ are independently selected from substituted C6-C39 aryl, substituted C5-C60 heteroaryl, substituted C6-C60 aryloxy, substituted C6-C39 arylamine, substituted C6-C39 arylboryl, substituted C6-C39 arylphosphino and substituted C6-C39 arylsilyl, the types of substituents for the C6-C39 aryl, C5-C60 heteroaryl, C6-C60 aryloxy, C6-C39 arylamine, C6-C39 arylboryl, C6-C39 arylphosphino and C6-C39 arylsilyl are not limited here.

For example, the substituents for the C6-C39 aryl, C5-C60 heteroaryl, C6-C60 aryloxy, C6-C39 arylamine, C6-C39 arylboryl, C6-C39 arylphosphino and C6-C39 arylsilyl are independently hydrogen atom, deuterium atom, substituted or unsubstituted C1-C39 alkyl, substituted or unsubstituted C2-C39 alkenyl, substituted or unsubstituted C2-C39 alkynyl, substituted or unsubstituted C1-C39 alkoxy, substituted or unsubstituted C3-C39 cycloalkyl, substituted or unsubstituted C3-C39 heterocycloalkyl, substituted or unsubstituted C1-C39 alkylsilyl, or substituted or unsubstituted C1-C39 alkylboryl. As for the description of the term “Cx alkyl”, reference may be made to the above description of the “Cx aryl”, and details will not be repeated here.

Based on the above structure of the first functional material GF1, the part IB and the part IC are both triarylamine groups, so that the first functional material GF1 is a hole-type material, which may be used to transport holes and block electrons. In this way, the first-type functional layer 133 containing the first functional material GF1 may achieve effective hole injection and fast hole transport. Moreover, in the structure represented by the general formula (I), the phenanthroline group of the part IA is a part of the first functional material GF1 that serves as an electron acceptor, and the triarylamine groups of the part IB and the part IC are the parts of the first functional material GF1 that serve as electron donors; in comparison with the aromatic amine material of the first-type functional layer 133 in the above-mentioned implementation, the phenanthroline group is added in the first functional material GF1 to serve as the electron acceptor; in this way, in a compound molecule of the first functional material GF1, a lowest unoccupied molecular orbital (LUMO) is distributed in the electron acceptor (i.e., the phenanthroline group), so that the electrons are limitedly distributed in a fragment corresponding to the phenanthroline group, and thus it is possible to prevent the carbon-nitrogen bond from breaking caused by a case that the electrons attack the carbon-nitrogen bond. Therefore, the electron stability of the first functional material GF1 is effectively improved, which may improve the stability of the light-emitting device 10 and extend the service life of the light-emitting device 10.

For example, a distribution of the lowest unoccupied molecular orbital (LUMO) of the first functional material GF1 is as shown in FIG. 6; a distribution of a highest occupied molecular orbital (HOMO) of the first functional material GF1 is as shown in FIG. 7. As can be seen from FIG. 6, the lowest unoccupied molecular orbital (LUMO) of the first functional material GF1 is mainly distributed in the part (i.e., the part indicated by K in the figure) corresponding to the phenanthroline group.

The structure formula of the first functional material GF1 represented by the general formula (I) will be schematically described below.

In some examples, in a case where L₁ is phenylene, L₂ is

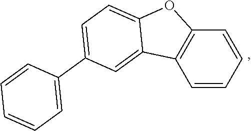 [SMILES: c1ccc(-c2ccc3oc4ccccc4c3c2)cc1]

and

### Ar₁ is

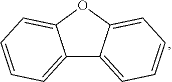 [SMILES: c1ccc2c(c1)oc1ccccc12]

the structural formulas of the first functional material GF1 may be as shown in the following formulas.

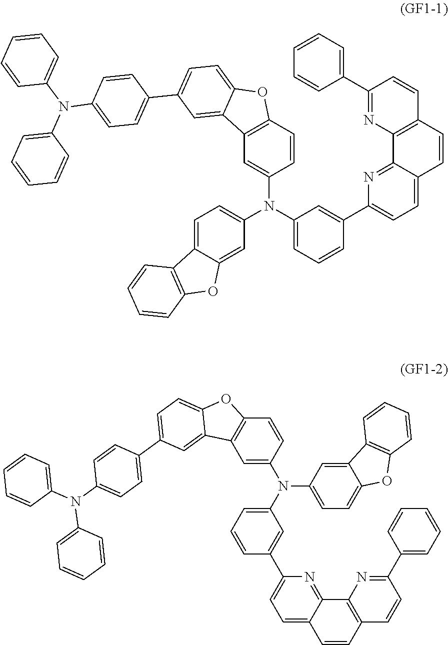 [SMILES: c1ccc(-c2ccc3ccc4ccc(-c5cccc(N(c6ccc7c(c6)oc6ccccc67)c6ccc7oc8ccc(-c9ccc(N(c%10ccccc%10)c%10ccccc%10)cc9)cc8c7c6)c5)nc4c3n2)cc1 ; c1ccc(-c2ccc3ccc4ccc(-c5cccc(N(c6ccc7oc8ccccc8c7c6)c6ccc7oc8ccc(-c9ccc(N(c%10ccccc%10)c%10ccccc%10)cc9)cc8c7c6)c5)nc4c3n2)cc1]

It will be noted that, “(GF1-x)” in the above structural formulas is an alternative name of each structural formula and is not part of the structure of the structural formula, where x is a positive integer.

From the first functional materials GF1 represented by above structural formulas (GF1-1) and (GF1-2), it can be seen that the phenanthroline group in the part IA of the structure shown in the general formula (I) may be a substituted phenanthroline group. For example, in the first functional materials GF1 represented by the above structural formulas (GF1-1) and (GF1-2), the part IA is a phenyl substituted phenanthroline group.

In order to improve the molecular stability of the first functional material GF1, in some embodiments, the structure represented by the general formula (I) contains at least one deuterium atom. That is, the first functional material GF1 may be selected from any one of the structures represented by the following general formula (I′).

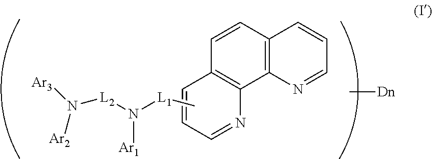

In the above general formula, n is a positive integer greater than or equal to 1.

Since the atomic weight of deuterium is twice that of hydrogen, with the provision of at least one deuterium atom in the structure represented by the general formula (I), the physical properties of the first functional material GF1 changes; in particular, an atom in the structure formula of the first functional material GF1 is substituted with a deuterium atom, it is possible to effectively suppress molecular vibration, reduce bond length and increase bond energy, thereby improving the molecular stability. Thus, the stability of the first functional material GF1 is improved.

It will be noted that, the structure represented by the general formula (I) contains at least one deuterium atom, which means that the structure represented by the general formula (I) satisfies at least one of the following four conditions: (1) L₁ is selected from one of deuterated arylene and deuterated heteroarylene; (2) L₂ is selected from one of deuterated arylene and deuterated heteroarylene; (3) at least one of Ar₁, Ar₂ and Ar₃ is selected from one of deuterated aryl, deuterated heteroaryl, deuterated aryloxy, deuterated arylamine, deuterated arylboryl, deuterated arylphosphino and deuterated arylsilyl; (4) the phenanthroline group is a deuterated phenanthroline group.

In some embodiments, the first functional material GF1 is selected from any one of the structures represented by the following general formula (IV).

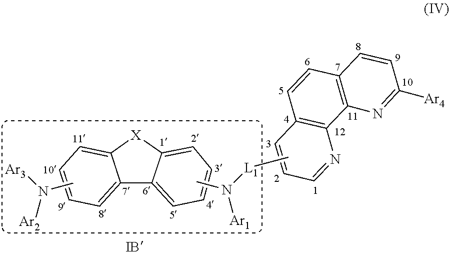

X is selected from any one of O, S, N(R₂) and C(R₃R₄).

R₂, R₃, R₄ and Ar₄ are the same or different and are independently selected from any one of hydrogen, deuterium, substituted or unsubstituted C1-C39 alkyl, substituted or unsubstituted C2-C39 alkenyl, substituted or unsubstituted C2-C39 alkynyl, substituted or unsubstituted C6-C39 aryl, substituted or unsubstituted C5-C60 heteroaryl, substituted or unsubstituted C6-C60 aryloxy, substituted or unsubstituted C1-C39 alkoxy, substituted or unsubstituted C6-C39 arylamine, substituted or unsubstituted C3-C39 cycloalkyl, substituted or unsubstituted C3-C39 heterocycloalkyl, substituted or unsubstituted C1-C39 alkylsilyl, substituted or unsubstituted C1-C39 alkylboryl, substituted or unsubstituted C6-C39 arylboryl, substituted or unsubstituted C6-C39 arylphosphino and substituted or unsubstituted C6-C39 arylsilyl.

It will be understood that, in the structure represented by the general formula (I), in a case where L₂ is selected from

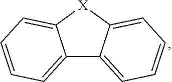

and the phenanthroline group is substituted by Ar₄ at 10-position carbon atom, the structure represented by the general formula (I) may be transformed into the structure represented by the general formula (IV), where L₂ is

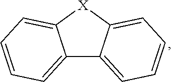

and the part IB in the structure shown in the general formula (I) is transformed into the part IB′ in the structure shown in the general formula (IV).

Regarding the structure represented by the general formula (IV), several points need to be explained below.

X is selected from any one of O, S, N(R₂) and C(R₃R₄), where O represents an oxygen atom; S represents a sulfur atom; N(R₂) represents that one atom bonded to nitrogen is substituted with R₂; C(R₃R₄) represents that two atoms bonded to carbon are respectively substituted with R₃ and R₄, and R₃ and R₄ may be the same or different.

Here, a nitrogen atom in the part IB′ of the structure shown in the general formula (IV) is marked as 1-position nitrogen atom, and a nitrogen atom linked to Ar₂ and Ar₃ is marked as 2-position nitrogen atom. In the structure represented by the general formula (IV), the 1-position nitrogen atom and 2-position nitrogen atom are linked to

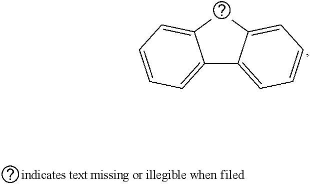

which means that the 1-position nitrogen atom and 2-position nitrogen atom may be linked to any two of 2′-position, 3′-position, 4′-position, 5′-position, 8′-position, 9′-position, 10′-position, and 11′-position carbon atoms; that is, the 1-position nitrogen atom and 2-position nitrogen atom may be linked to any two carbon atoms, each of which has a substitutable position, of 2′-position, 3′-position, 4′-position, 5′-position, 8′-position, 9′-position, 10′-position, and 11′-position carbon atoms. That is, the carbon atom linked to the 1-position nitrogen atom is not a same carbon atom as the carbon atom linked to the 2-position nitrogen atom.

In a case where R₂, R₃, R₄ and Ar₄ are selected from substituted C1-C39 alkyl, substituted C2-C39 alkenyl, substituted C2-C39 alkynyl, substituted C6-C39 aryl, substituted C5-C60 heteroaryl, substituted C6-C60 aryloxy, substituted C1-C39 alkoxy, substituted C6-C39 arylamine, substituted C3-C39 cycloalkyl, substituted C3-C39 heterocycloalkyl, substituted C1-C39 alkylsilyl, substituted C1-C39 alkylboryl, substituted C6-C39 arylboryl, substituted C6-C39 arylphosphino and substituted C6-C39 arylsilyl, the types of the substituents are not limited here.

Here, the description of a connection between L₁ and the phenanthroline group shown in the general formula (IV) may refer to the above content; the description of the terms “Cx aryl” and “Cx alkyl” may refer to the above description of the terms “Cx aryl” and “Cx alkyl”; the description of aryl and heteroaryl may refer to the above description of aryl and heteroaryl, and details will not be repeated here.

The structure formula of the first functional material GF1 represented by the general formula (IV) will be schematically described below.

In some examples, in a case where L₁ is phenylene, X is oxygen, and Ar₁ is phenyl, the structural formula of the first functional material GF1 may be as shown in the following.

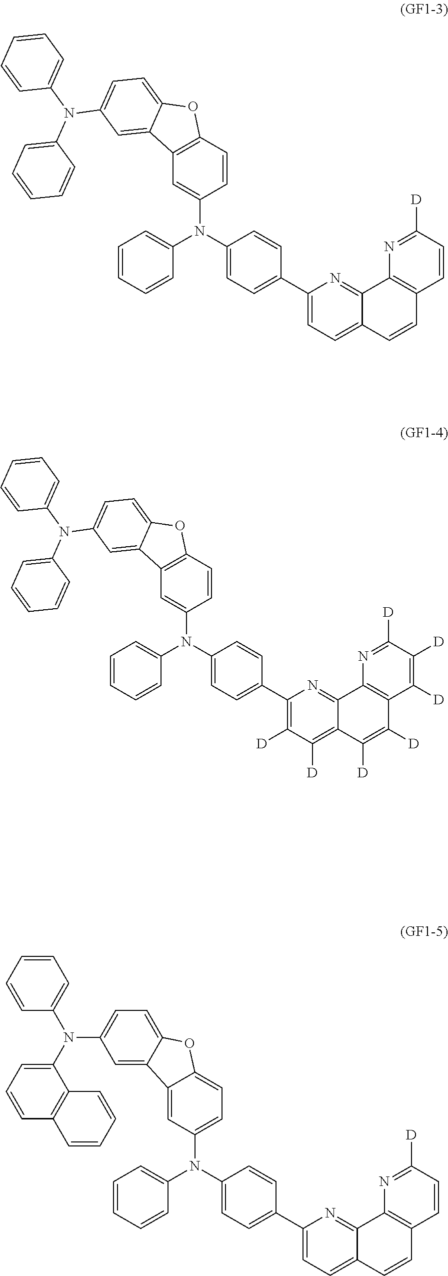 [SMILES: [2H]c1ccc2ccc3ccc(-c4ccc(N(c5ccccc5)c5ccc6oc7ccc(N(c8ccccc8)c8ccccc8)cc7c6c5)cc4)nc3c2n1 ; [2H]c1nc2c(c([2H])c1[2H])c([2H])c([2H])c1c([2H])c([2H])c(-c3ccc(N(c4ccccc4)c4ccc5oc6ccc(N(c7ccccc7)c7ccccc7)cc6c5c4)cc3)nc12 ; [2H]c1ccc2ccc3ccc(-c4ccc(N(c5ccccc5)c5ccc6oc7ccc(N(c8ccccc8)c8cccc9ccccc89)cc7c6c5)cc4)nc3c2n1]

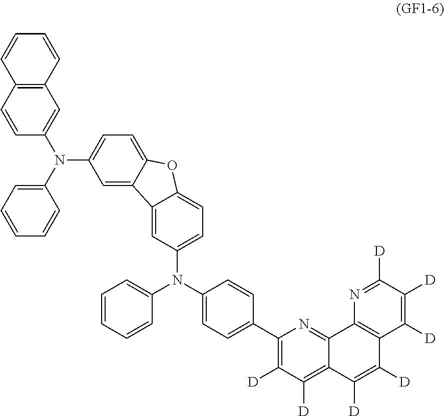 [SMILES: [2H]c1nc2c(c([2H])c1[2H])c([2H])c([2H])c1c([2H])c([2H])c(-c3ccc(N(c4ccccc4)c4ccc5oc6ccc(N(c7ccccc7)c7ccc8ccccc8c7)cc6c5c4)cc3)nc12]

In some examples, in a case where L₁ is phenylene, X is oxygen, and Ar₁ is

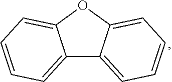 [SMILES: c1ccc2c(c1)oc1ccccc12]

the structural formula of the first functional material GF1 may be as shown in the following.

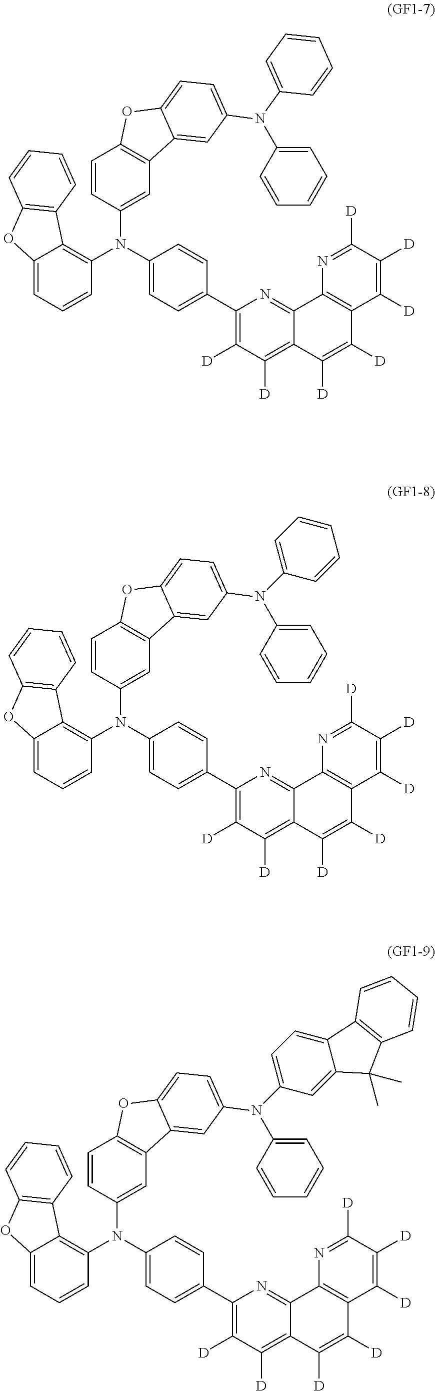 [SMILES: [2H]c1nc2c(c([2H])c1[2H])c([2H])c([2H])c1c([2H])c([2H])c(-c3ccc(N(c4ccc5oc6ccc(N(c7ccccc7)c7ccccc7)cc6c5c4)c4cccc5oc6ccccc6c45)cc3)nc12 ; [2H]c1nc2c(c([2H])c1[2H])c([2H])c([2H])c1c([2H])c([2H])c(-c3ccc(N(c4ccc5oc6ccc(N(c7ccccc7)c7ccccc7)cc6c5c4)c4cccc5oc6ccccc6c45)cc3)nc12 ; [2H]c1nc2c(c([2H])c1[2H])c([2H])c([2H])c1c([2H])c([2H])c(-c3ccc(N(c4ccc5oc6ccc(N(c7ccccc7)c7ccc8c(c7)C(C)(C)c7ccccc7-8)cc6c5c4)c4cccc5oc6ccccc6c45)cc3)nc12]

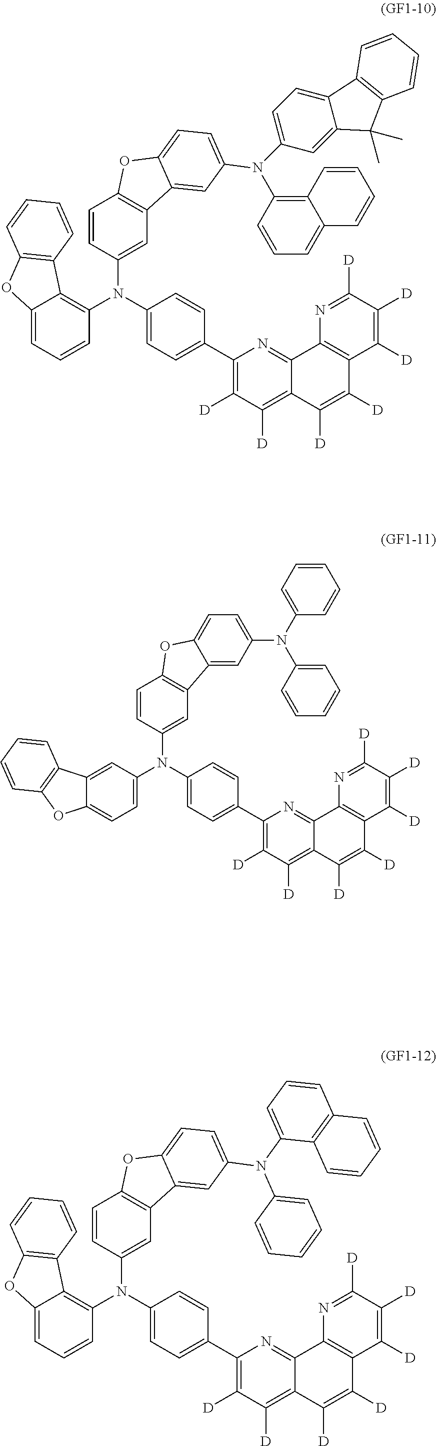 [SMILES: [2H]c1nc2c(c([2H])c1[2H])c([2H])c([2H])c1c([2H])c([2H])c(-c3ccc(N(c4ccc5oc6ccc(N(c7ccc8c(c7)C(C)(C)c7ccccc7-8)c7cccc8ccccc78)cc6c5c4)c4cccc5oc6ccccc6c45)cc3)nc12 ; [2H]c1nc2c(c([2H])c1[2H])c([2H])c([2H])c1c([2H])c([2H])c(-c3ccc(N(c4ccc5oc6ccccc6c5c4)c4ccc5oc6ccc(N(c7ccccc7)c7ccccc7)cc6c5c4)cc3)nc12 ; [2H]c1nc2c(c([2H])c1[2H])c([2H])c([2H])c1c([2H])c([2H])c(-c3ccc(N(c4ccc5oc6ccc(N(c7ccccc7)c7cccc8ccccc78)cc6c5c4)c4cccc5oc6ccccc6c45)cc3)nc12]

In some examples, in a case where L₁ is phenylene, X is oxygen, and Ar₁ is

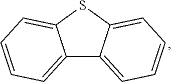 [SMILES: c1ccc2c(c1)sc1ccccc12]

the structural formula of the first functional material GF1 may be as shown in the following formulas.

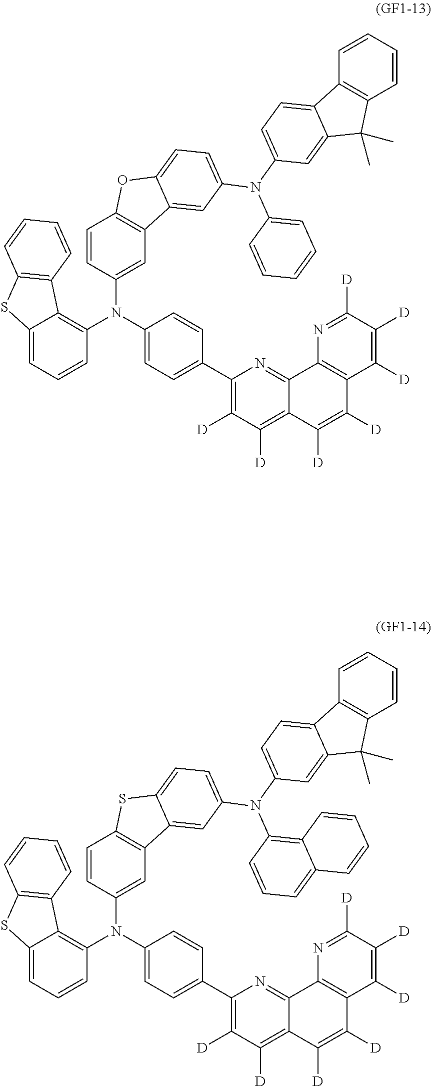 [SMILES: [2H]c1nc2c(c([2H])c1[2H])c([2H])c([2H])c1c([2H])c([2H])c(-c3ccc(N(c4ccc5oc6ccc(N(c7ccccc7)c7ccc8c(c7)C(C)(C)c7ccccc7-8)cc6c5c4)c4cccc5sc6ccccc6c45)cc3)nc12 ; [2H]c1nc2c(c([2H])c1[2H])c([2H])c([2H])c1c([2H])c([2H])c(-c3ccc(N(c4ccc5sc6ccc(N(c7ccc8c(c7)C(C)(C)c7ccccc7-8)c7cccc8ccccc78)cc6c5c4)c4cccc5sc6ccccc6c45)cc3)nc12]

In some examples, in a case where L₁ is phenylene, X is sulfur, and Ar₁ is phenyl, the structural formula of the first functional material GF1 may be as shown in the following.

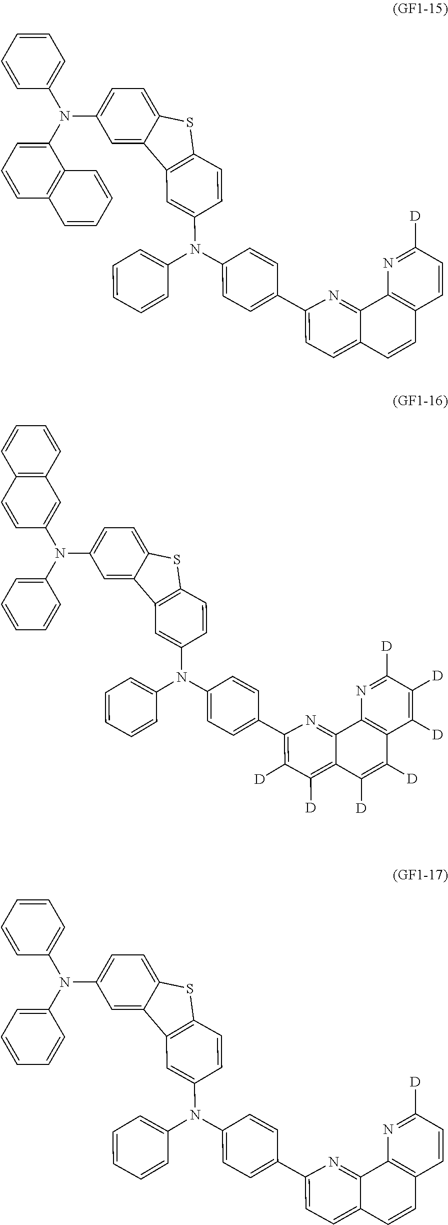 [SMILES: [2H]c1ccc2ccc3ccc(-c4ccc(N(c5ccccc5)c5ccc6sc7ccc(N(c8ccccc8)c8cccc9ccccc89)cc7c6c5)cc4)nc3c2n1 ; [2H]c1nc2c(c([2H])c1[2H])c([2H])c([2H])c1c([2H])c([2H])c(-c3ccc(N(c4ccccc4)c4ccc5sc6ccc(N(c7ccccc7)c7ccc8ccccc8c7)cc6c5c4)cc3)nc12 ; [2H]c1ccc2ccc3ccc(-c4ccc(N(c5ccccc5)c5ccc6sc7ccc(N(c8ccccc8)c8ccccc8)cc7c6c5)cc4)nc3c2n1]

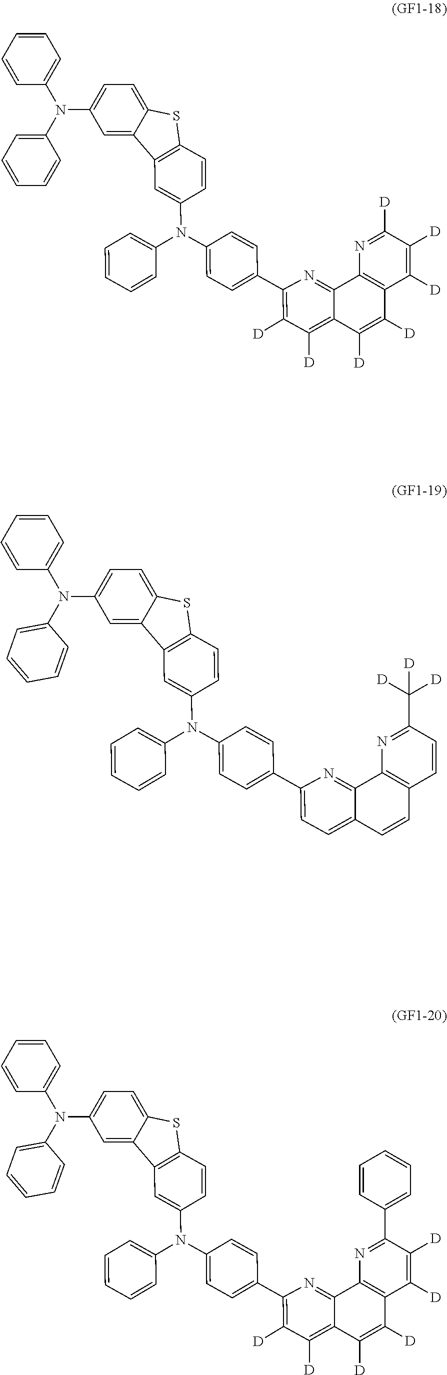 [SMILES: [2H]c1nc2c(c([2H])c1[2H])c([2H])c([2H])c1c([2H])c([2H])c(-c3ccc(N(c4ccccc4)c4ccc5sc6ccc(N(c7ccccc7)c7ccccc7)cc6c5c4)cc3)nc12 ; [2H]C([2H])([2H])c1ccc2ccc3ccc(-c4ccc(N(c5ccccc5)c5ccc6sc7ccc(N(c8ccccc8)c8ccccc8)cc7c6c5)cc4)nc3c2n1 ; [2H]c1c(-c2ccccc2)nc2c(c1[2H])c([2H])c([2H])c1c([2H])c([2H])c(-c3ccc(N(c4ccccc4)c4ccc5sc6ccc(N(c7ccccc7)c7ccccc7)cc6c5c4)cc3)nc12]

In some examples, in a case where L₁ is phenylene, X is, and Ar₁ is

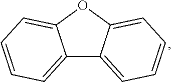 [SMILES: c1ccc2c(c1)oc1ccccc12]

the structural formula of the first functional material GF1 may be as shown in the following.

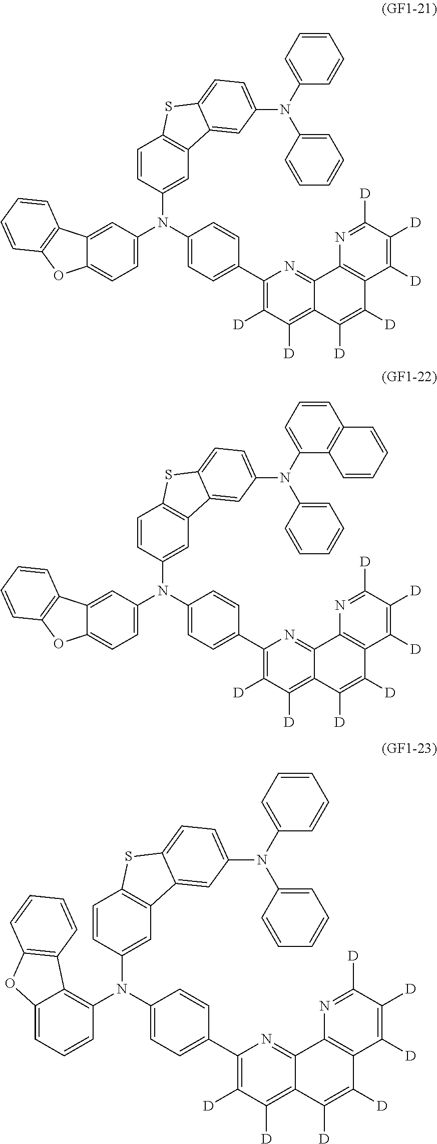 [SMILES: [2H]c1nc2c(c([2H])c1[2H])c([2H])c([2H])c1c([2H])c([2H])c(-c3ccc(N(c4ccc5oc6ccccc6c5c4)c4ccc5sc6ccc(N(c7ccccc7)c7ccccc7)cc6c5c4)cc3)nc12 ; [2H]c1nc2c(c([2H])c1[2H])c([2H])c([2H])c1c([2H])c([2H])c(-c3ccc(N(c4ccc5oc6ccccc6c5c4)c4ccc5sc6ccc(N(c7ccccc7)c7cccc8ccccc78)cc6c5c4)cc3)nc12 ; [2H]c1nc2c(c([2H])c1[2H])c([2H])c([2H])c1c([2H])c([2H])c(-c3ccc(N(c4ccc5sc6ccc(N(c7ccccc7)c7ccccc7)cc6c5c4)c4cccc5oc6ccccc6c45)cc3)nc12]

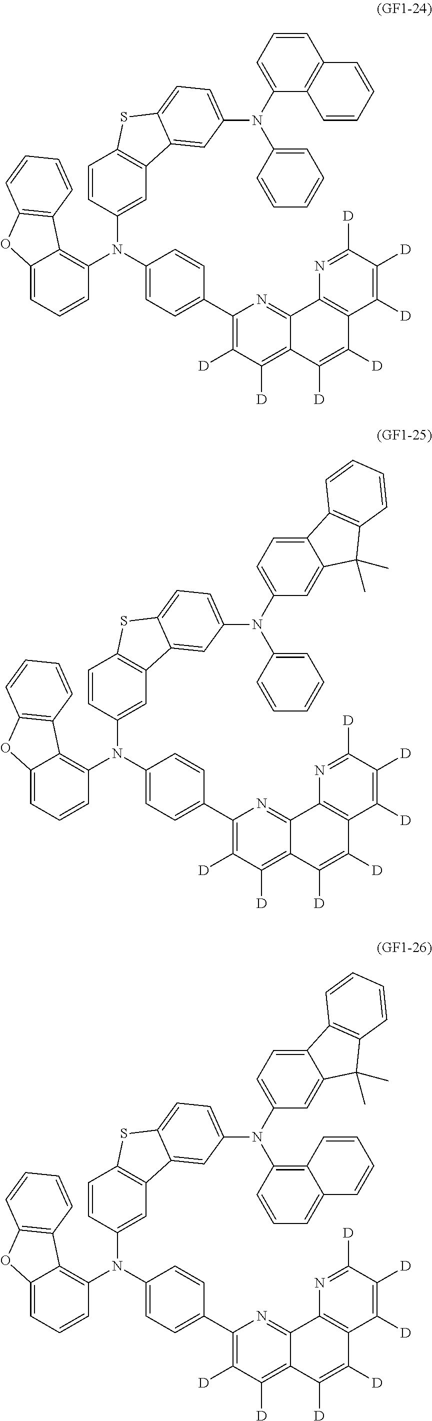 [SMILES: [2H]c1nc2c(c([2H])c1[2H])c([2H])c([2H])c1c([2H])c([2H])c(-c3ccc(N(c4ccc5sc6ccc(N(c7ccccc7)c7cccc8ccccc78)cc6c5c4)c4cccc5oc6ccccc6c45)cc3)nc12 ; [2H]c1nc2c(c([2H])c1[2H])c([2H])c([2H])c1c([2H])c([2H])c(-c3ccc(N(c4ccc5sc6ccc(N(c7ccccc7)c7ccc8c(c7)C(C)(C)c7ccccc7-8)cc6c5c4)c4cccc5oc6ccccc6c45)cc3)nc12 ; [2H]c1nc2c(c([2H])c1[2H])c([2H])c([2H])c1c([2H])c([2H])c(-c3ccc(N(c4ccc5sc6ccc(N(c7ccc8c(c7)C(C)(C)c7ccccc7-8)c7cccc8ccccc78)cc6c5c4)c4cccc5oc6ccccc6c45)cc3)nc12]

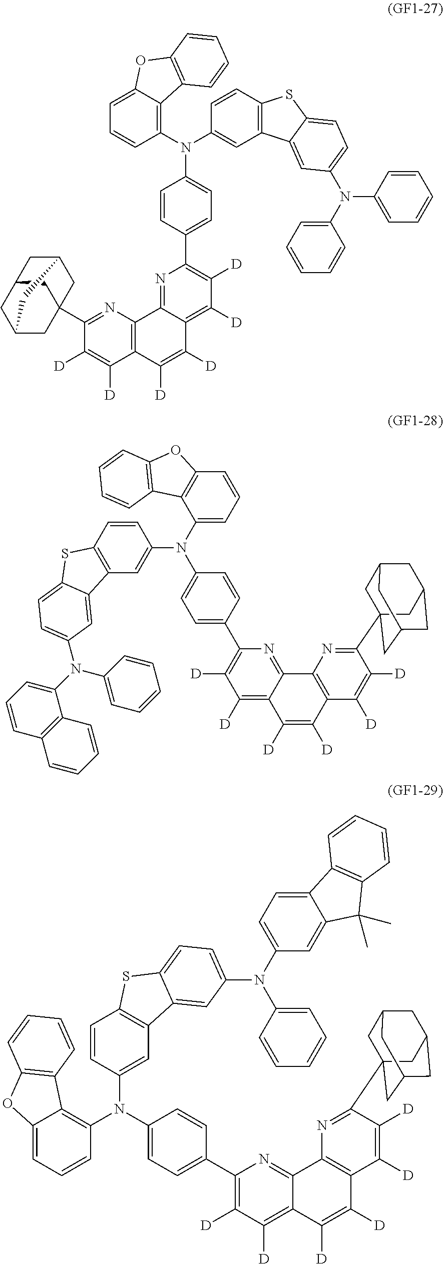 [SMILES: [2H]c1c(-c2ccc(N(c3ccc4sc5ccc(N(c6ccccc6)c6ccccc6)cc5c4c3)c3cccc4oc5ccccc5c34)cc2)nc2c(c1[2H])c([2H])c([2H])c1c([2H])c([2H])c(C34C[C@H]5C[C@@H](C3)C[C@@H](C4)C5)nc12 ; [2H]c1c(-c2ccc(N(c3ccc4sc5ccc(N(c6ccccc6)c6cccc7ccccc67)cc5c4c3)c3cccc4oc5ccccc5c34)cc2)nc2c(c1[2H])c([2H])c([2H])c1c([2H])c([2H])c(C34CC5CC(CC(C5)C3)C4)nc12 ; [2H]c1c(-c2ccc(N(c3ccc4sc5ccc(N(c6ccccc6)c6ccc7c(c6)C(C)(C)c6ccccc6-7)cc5c4c3)c3cccc4oc5ccccc5c34)cc2)nc2c(c1[2H])c([2H])c([2H])c1c([2H])c([2H])c(C34CC5CC(CC(C5)C3)C4)nc12]

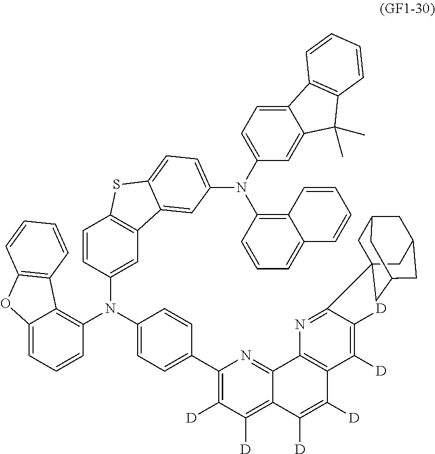 [SMILES: [2H]c1c(-c2ccc(N(c3ccc4sc5ccc(N(c6ccc7c(c6)C(C)(C)c6ccccc6-7)c6cccc7ccccc67)cc5c4c3)c3cccc4oc5ccccc5c34)cc2)nc2c(c1[2H])c([2H])c([2H])c1c([2H])c([2H])c(C34CC5CC(CC(C5)C3)C4)nc12]

In some examples, in a case where L₁ is phenylene, X is sulfur, and Ar₁ is

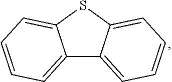 [SMILES: c1ccc2c(c1)sc1ccccc12]

the structural formula of the first functional material GF1 may be as shown in the following.

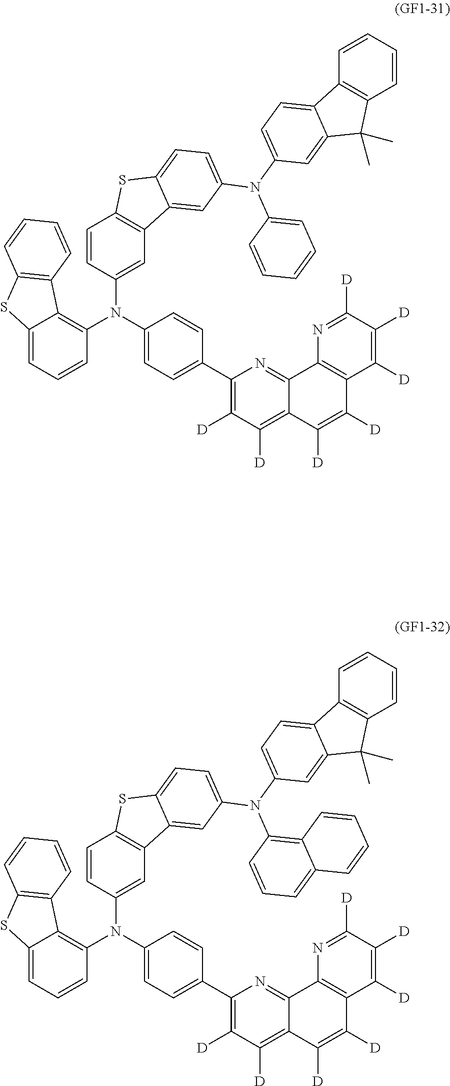 [SMILES: [2H]c1nc2c(c([2H])c1[2H])c([2H])c([2H])c1c([2H])c([2H])c(-c3ccc(N(c4ccc5sc6ccc(N(c7ccccc7)c7ccc8c(c7)C(C)(C)c7ccccc7-8)cc6c5c4)c4cccc5sc6ccccc6c45)cc3)nc12 ; [2H]c1nc2c(c([2H])c1[2H])c([2H])c([2H])c1c([2H])c([2H])c(-c3ccc(N(c4ccc5sc6ccc(N(c7ccc8c(c7)C(C)(C)c7ccccc7-8)c7cccc8ccccc78)cc6c5c4)c4cccc5sc6ccccc6c45)cc3)nc12]

It will be noted that, “(GF1-x)” in the above structural formulas is an alternative name of each structural formula and is not part of the structure of the structural formula, where x is a positive integer.

It will be noted that, in a case where Ar₁ is

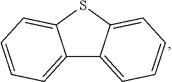 [SMILES: c1ccc2c(c1)sc1ccccc12]

a position of Ar₁ to which the 1-position nitrogen atom is linked is not limited here.

From the first functional material GF1 represented by any of the above structural formulas (GF1-7) to (GF1-12) and (GF1-21) to (GF1-30), it can be seen that in the structure represented by the general formula (IV), in a case where Ar₁ is

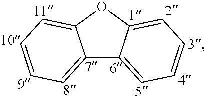

the position of Ar₁ to which the 1-position nitrogen atom is linked is not limited here. For example, as shown in the general formulas (GF1-11), (GF1-12), (GF1-21) and (GF1-22), the 1-position nitrogen atom is linked to Ar₁ at the 4″-position carbon atom; alternatively, as shown in the general formulas (GF1-7) to (GF1-10) and (GF1-23) to (GF1-30), the 1-position nitrogen atom is linked to Ar₁ at the 5″-position carbon atom.

From the first functional material GF1 represented by any of the above structural formulas (GF1-3) to (GF1-32), it can be seen that in the structure represented by the general formula (IV), the substituent Ar₄ for the 10-position carbon atom of the phenanthroline group may be selected from one of hydrogen, deuterium, alkyl, aryl, or cycloalkyl. For example, as shown in the above structural formulas (GF1-3) to (GF1-18) and (GF1-21) to (GF1-26), Ar₄ may be selected from hydrogen or deuterium; alternatively, as shown in the above structural formula (GF1-19), Ar₄ may be selected from an alkyl (deuterated methyl); alternatively, as shown in the above structural formula (GF1-20), Ar₄ may be selected from phenyl; as shown in the above structural formulas (GF1-27) to (GF1-32), Ar₄ may be selected from cycloalkyl.

The structure of the first functional material GF1 represented by the general formula (IV) are schematically described above.

In order to improve the molecular stability of the first functional material GF1, in some embodiments, the structure represented by the general formula (IV) contains at least one deuterium atom. That is, the first functional material GF1 may be selected from any one of the structures represented by the general formula (IV′).

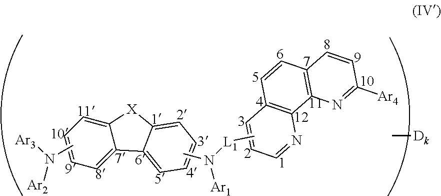

In the above general formula, k is a positive integer greater than or equal to 1.

Since the atomic weight of deuterium is twice that of hydrogen, with the provision of at least one deuterium atom in the structure represented by the general formula (IV), the physical properties of the first functional material GF1 changes; in particular, an atom in the structure formula of the first functional material GF1 is substituted with a deuterium atom, it is possible to effectively suppress molecular vibration, reduce bond length and increase bond energy, thereby improving the molecular stability. Thus, the stability of the first functional material GF1 is improved.

It will be noted that, the structure represented by the general formula (IV) contains at least one deuterium atom, which means that the structure represented by the general formula (IV) satisfies at least one of the following five conditions: (1) L₁ is selected from one of deuterated arylene and deuterated heteroarylene; (2) at least one of Ar₁, Ar₂ and Ar₃ is selected from one of deuterated aryl, deuterated heteroaryl, deuterated aryloxy, deuterated arylamine, deuterated arylboryl, deuterated arylphosphino and deuterated arylsilyl; (3) the phenanthroline group is a deuterated phenanthroline group; (4) Ar₄ is selected from deuterium, deuterated alkyl, deuterated alkenyl, deuterated alkynyl, deuterated aryl, deuterated heteroaryl, deuterated aryloxy, deuterated alkoxy, deuterated arylamine, deuterated cycloalkyl, deuterated heterocycloalkyl, deuterated alkylsilyl, deuterated alkylboryl, deuterated arylboryl, deuterated arylphosphino and deuterated arylsilyl; (5) at least one deuterium atom is contained in the part IB′.

For example, in the first functional material GF1 represented by any of the above structural formulas (GF1-3), (GF1-5), (GF1-15) and (GF1-17), Ar₄ is deuterium.

For example, in the first functional material GF1 represented by the above structural formula (GF1-19), Ar₄ is deuterated methyl.

For example, in the first functional material GF1 represented by any of the above structural formulas (GF1-4), (GF1-6), (GF1-7) to (GF1-14), (GF1-16), (GF1-18), and (GF1-20) to (GF1-30), among the 1-position, 2-position, 3-position, 5-position, 6-position, 8-position, and 9-position carbon atoms of the phenanthroline group, except the carbon atom that is linked to the 1-position nitrogen atom, the remaining carbon atoms are all provided with deuterium substituents; in this case, k is a positive integer greater than or equal to 6.

The structure of the material (i.e., the first functional material GF1) of the auxiliary functional layer 1334 is described above, and a position of the auxiliary functional layer 1334 in the light-emitting device 10 will be described below.

In some embodiments, as shown in FIG. 4, the first-type functional layer 133 is located on a side of the light-emitting layer 131 proximate to the anode 11; and the auxiliary functional layer 1334 is configured to block electrons.

It can be seen from the above that the first functional material GF1 is a hole-type material, which may be used to transport holes and block electrons. In the case where the first-type functional layer 133 includes the auxiliary functional layer 1334 and the material of the auxiliary functional layer 1334 includes the first functional material GF1, the first-type functional layer 133 is disposed on the side of the light-emitting layer 131 proximate to the anode 11, so that the auxiliary functional layer 1334 may play a role of blocking electrons. Moreover, when the auxiliary functional layer 1334 containing the first functional material GF1 blocks electrons and is attacked by electrons, the phenanthroline group in the structure of the first functional material GF1 may act as an electron acceptor, so that the electrons are limitedly distributed in the segment corresponding to the phenanthroline group to prevent the electrons from attacking the carbon-nitrogen bond and causing the carbon-nitrogen bond to break. In this way, in comparison with the aromatic amine material of the first-type functional layer 133 in the above implementation, the electronic stability of the first-type functional layer 133 in the embodiments of the present disclosure is effectively improved, so that the stability of the light-emitting device 10 may be improved and the service life of the light-emitting device 10 may be extended.

In some embodiments, the first-type functional layer 133 further includes the electron blocking layer 1333 stacked with the auxiliary functional layer 1334, a material of the electron blocking layer 1333 includes a second functional material GF2, and the second functional material GF2 is selected from any one of the structures represented by the following general formula (II).

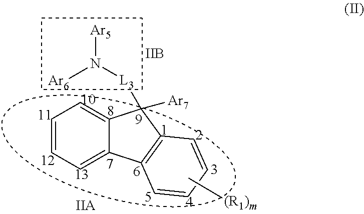

In the above general formula, L₃ is selected from any one of single bond, substituted or unsubstituted C3-C30 arylene, and substituted or unsubstituted C3-C30 heteroarylene.

Ar₅ and Ar₆ are the same or different, and are independently selected from any one of substituted or unsubstituted C6-C39 aryl, substituted or unsubstituted C5-C60 heteroaryl, substituted or unsubstituted C6-C60 aryloxy, substituted or unsubstituted C6-C39 arylamine, substituted or unsubstituted C6-C39 arylboryl, substituted or unsubstituted C6-C39 arylphosphino, and substituted or unsubstituted C6-C39 arylsilyl.

Ar₇ and R₁ are the same or different, and are independently selected from any one of hydrogen, deuterium, substituted or unsubstituted C1-C39 alkyl, substituted or unsubstituted C2-C39 alkenyl, substituted or unsubstituted C2-C39 alkynyl, substituted or unsubstituted C6-C39 aryl, substituted or unsubstituted C5-C60 heteroaryl, substituted or unsubstituted C6-C60 aryloxy, substituted or unsubstituted C1-C39 alkoxy, substituted or unsubstituted C6-C39 arylamine, substituted or unsubstituted C3-C39 cycloalkyl, substituted or unsubstituted C3-C39 heterocycloalkyl, substituted or unsubstituted C1-C39 alkylsilyl, substituted or unsubstituted C1-C39 alkylboryl, substituted or unsubstituted C6-C39 arylboryl, substituted or unsubstituted C6-C39 arylphosphino, and substituted or unsubstituted C6-C39 arylsilyl.

m is a positive integer greater than or equal to 1.

In the structure represented by the general formula (II), the part IIA is fluorene, and the part IIB is a triarylamine group.

Regarding the structure represented by the general formula (II), several points need to be explained below.

L₃ may be a single bond, and in a case where L₃ is a single bond, the 9-position carbon atom in the fluorene of the part IIA and the nitrogen atom in the part IIB are directly connected by a covalent bond.

A position where R₁ is linked to the fluorene of the part IIA shown in the general formula (II) means that R₁ may be linked to any one of 2-position, 3-position, 5-position, 6-position, 10-position, 11-position, 12-position, and 13-position carbon atom; that is, R₁ may be linked to any one of the 2-position, 3-position, 5-position, 6-position, 10-position, 11-position, 12-position, and 13-position carbon atom that has a substitutable position.

In a case where Ar₅ and Ar₆ are independently selected from substituted C6-C39 aryl, substituted C5-C60 heteroaryl, substituted C6-C60 aryloxy, substituted C6-C39 arylamine, substituted C6-C39 arylboryl, substituted C6-C39 arylphosphino, and substituted C6-C39 arylsilyl, the types of the substituents are not limited here.

For example, the substituents for the C6-C39 aryl, C5-C60 heteroaryl, C6-C60 aryloxy, C6-C39 arylamine, C6-C39 arylboryl, C6-C39 arylphosphino and C6-C39 arylsilyl are independently hydrogen, deuterium, substituted or unsubstituted C1-C39 alkyl, substituted or unsubstituted C2-C39 alkenyl, substituted or unsubstituted C2-C39 alkynyl, substituted or unsubstituted C1-C39 alkoxy, substituted or unsubstituted C3-C39 cycloalkyl, substituted or unsubstituted C3-C39 heterocycloalkyl, substituted or unsubstituted C1-C39 alkylsilyl, or substituted or unsubstituted C1-C39 alkylboryl.

Here, the description of the terms “Cx aryl” and “Cx alkyl” may refer to the above description of the terms “Cx aryl” and “Cx alkyl”; the description of aryl and heteroaryl may refer to the above description of aryl and heteroaryl; the description of arylene and heteroarylene may refer to the above description of arylene and heteroarylene, and details will not be repeated here.

Based on the above structure of the second functional material GF2, in the first aspect, the second functional material GF2 and the first functional material GF1 have matching energy levels and migration rates; in this way, in the case where the auxiliary functional layer 1334 containing the first functional material GF1 and the electron blocking layer 1333 containing the second functional material GF2 are stacked, the first functional material GF1 and the second functional material GF2 are used in combination to facilitate the transport of holes in the first-type functional layer 133. In the second aspect, with the provision of the triarylamine group at the 9-position carbon atom of the fluorene of the part IIA, the structural dimensionality of the second functional material GF2 may be improved, so that the second functional material GF2 is less likely to crystallize; in this way, the electron blocking layer 1333 containing the second functional material GF2 is stable, and the service life of the light-emitting device 10 is improved. In the third aspect, the second functional material GF2 is selected from any one of the structures represented by the general formula (II), so that the refractive index of the second functional material GF2 is reduced, which is conducive to improving the light extraction efficiency.

In some embodiments, the refractive index of the second functional material GF2 at 530 nm is in a range from 1.6 to 1.9. For example, the refractive index of the second functional material GF2 at 530 nm may be 1.6, 1.7, 1.8, or 1.9.

The structure of the second functional material GF2 represented by the general formula (II) will be schematically described below.

In some examples, in a case where L₃ is phenylene, Ar₇ is phenyl, and one of Ar₅ and Ar₆ is phenyl, the structural formula of the second functional material GF2 may be as shown in the following.

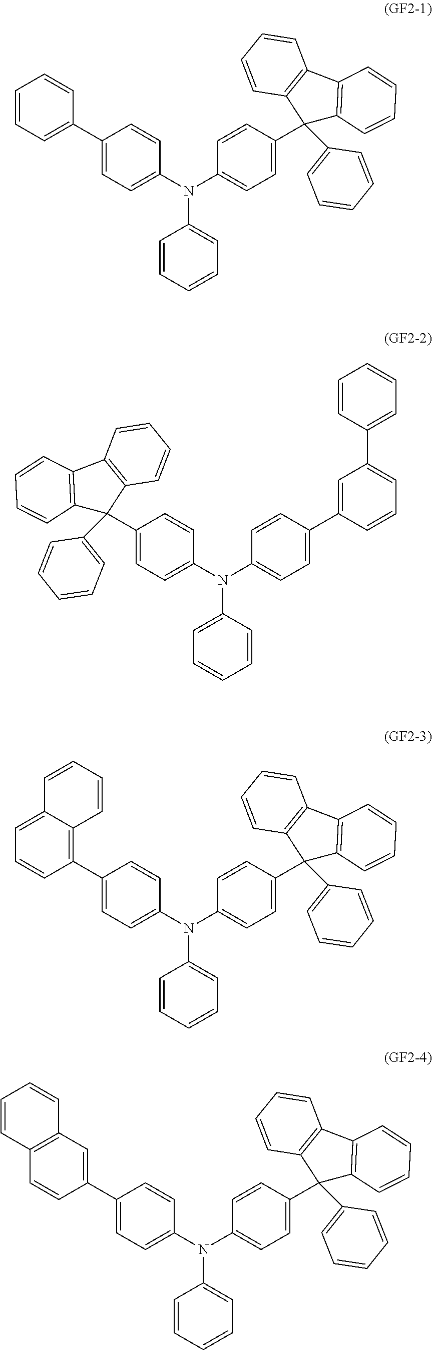 [SMILES: c1ccc(-c2ccc(N(c3ccccc3)c3ccc(C4(c5ccccc5)c5ccccc5-c5ccccc54)cc3)cc2)cc1 ; c1ccc(-c2cccc(-c3ccc(N(c4ccccc4)c4ccc(C5(c6ccccc6)c6ccccc6-c6ccccc65)cc4)cc3)c2)cc1 ; c1ccc(N(c2ccc(-c3cccc4ccccc34)cc2)c2ccc(C3(c4ccccc4)c4ccccc4-c4ccccc43)cc2)cc1 ; c1ccc(N(c2ccc(-c3ccc4ccccc4c3)cc2)c2ccc(C3(c4ccccc4)c4ccccc4-c4ccccc43)cc2)cc1]

In some examples, in a case where L₃ is phenylene, Ar₇ is phenyl, and one of Ar₅ and Ar₆ is biphenyl, the structural formula of the second functional material GF2 may be as shown in the following.

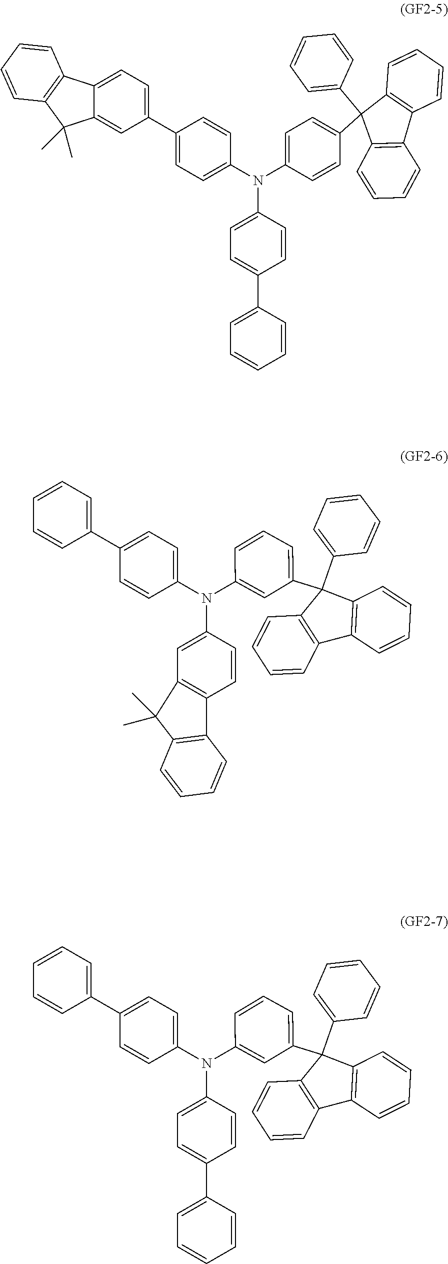 [SMILES: CC1(C)c2ccccc2-c2ccc(-c3ccc(N(c4ccc(-c5ccccc5)cc4)c4ccc(C5(c6ccccc6)c6ccccc6-c6ccccc65)cc4)cc3)cc21 ; CC1(C)c2ccccc2-c2ccc(N(c3ccc(-c4ccccc4)cc3)c3cccc(C4(c5ccccc5)c5ccccc5-c5ccccc54)c3)cc21 ; c1ccc(-c2ccc(N(c3ccc(-c4ccccc4)cc3)c3cccc(C4(c5ccccc5)c5ccccc5-c5ccccc54)c3)cc2)cc1]

In some examples, in a case where L₃ is

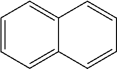

and Ar₇ is phenyl, the structural formula of the second functional material GF2 may be as shown in the following formula.

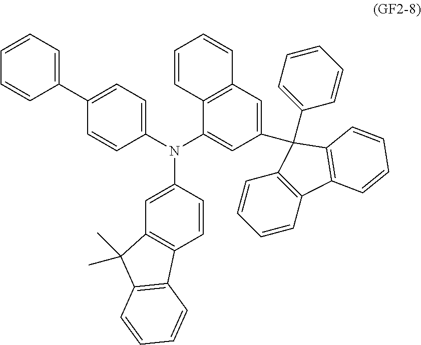 [SMILES: CC1(C)c2ccccc2-c2ccc(N(c3ccc(-c4ccccc4)cc3)c3cc(C4(c5ccccc5)c5ccccc5-c5ccccc54)cc4ccccc34)cc21]

It will be noted that, the terms “(GF2-x)” in the above structural formulas is an alternative name of each structural formula and is not part of the structure of the structural formula, where x is a positive integer.

In order to improve the molecular stability of the second functional material GF2, in some embodiments, at least one of Ar₅, Ar₆, Ar₇, L₃ and R₁ contains a deuterium atom.

Since the atomic weight of deuterium is twice that of hydrogen, with the provision of at least one deuterium atom in the structure represented by the general formula (II), the physical properties of the second functional material GF2 changes; in particular, an atom in the structure formula of the second functional material GF2 is substituted with a deuterium atom, it is possible to effectively suppress molecular vibration, reduce bond length and increase bond energy, thereby improving the molecular stability. Thus, the stability of the second functional material GF2 is improved.

It will be noted that, at least one of Ar₅, Ar₆, Ar₇, L₃ and R₁ contains a deuterium atom, which means that the structure represented by the general formula (II) satisfies at least one of the following four conditions: (1) the substituent for at least one of Ar₇ and R₁ is deuterium; (2) at least one of Ar₇ and R₁ is one of deuterated alkyl, deuterated alkenyl, deuterated alkynyl, deuterated aryl, deuterated heteroaryl, deuterated aryloxy, deuterated alkoxy, deuterated arylamine, deuterated cycloalkyl, deuterated heterocycloalkyl, deuterated alkylsilyl, deuterated alkylboryl, deuterated arylboryl, deuterated arylphosphino and deuterated arylsilyl; (3) L₃ is selected from one of deuterated arylene and deuterated heteroarylene; (4) at least one of Ar₅ and Ar₆ is one of deuterated aryl, deuterated heteroaryl, deuterated aryloxy, deuterated arylamine, deuterated arylboryl, deuterated arylphosphino and deuterated arylsilyl.

The structure of the second functional material GF2 will be described below in the case where at least one of Ar₅, Ar₆, Ar₇, L₃ and R₁ contains a deuterium atom.

In some examples, in a case where the deuterium atoms are all contained in L₃ in the structure of the second functional material GF2, L₃ is tetradeuterated phenylene, and Ar₇ is phenyl, the structural formula of the second functional material GF2 may be as shown in the following.

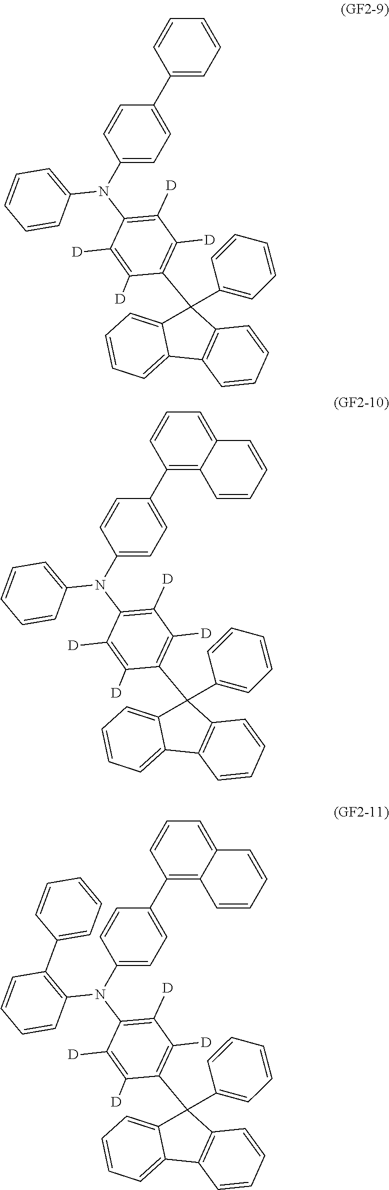

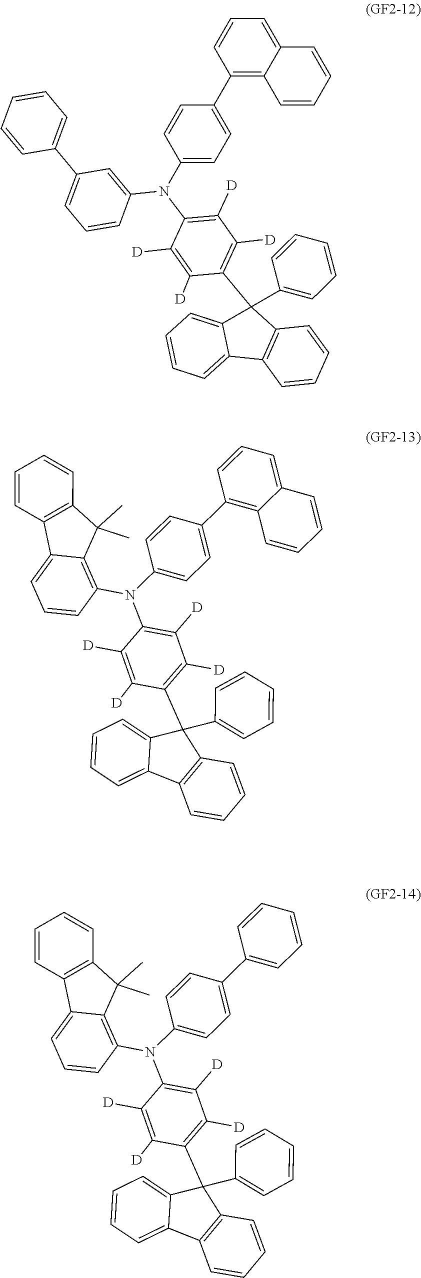 [SMILES: [2H]c1c([2H])c(C2(c3ccccc3)c3ccccc3-c3ccccc32)c([2H])c([2H])c1N(c1ccc(-c2cccc3ccccc23)cc1)c1cccc(-c2ccccc2)c1 ; [2H]c1c([2H])c(C2(c3ccccc3)c3ccccc3-c3ccccc32)c([2H])c([2H])c1N(c1ccc(-c2cccc3ccccc23)cc1)c1cccc2c1C(C)(C)c1ccccc1-2 ; [2H]c1c([2H])c(C2(c3ccccc3)c3ccccc3-c3ccccc32)c([2H])c([2H])c1N(c1ccc(-c2ccccc2)cc1)c1cccc2c1C(C)(C)c1ccccc1-2]

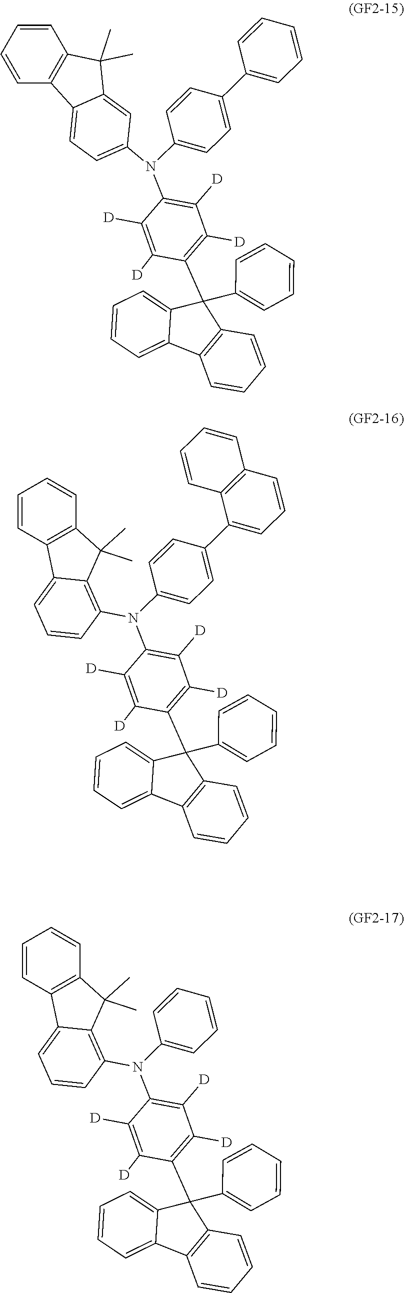

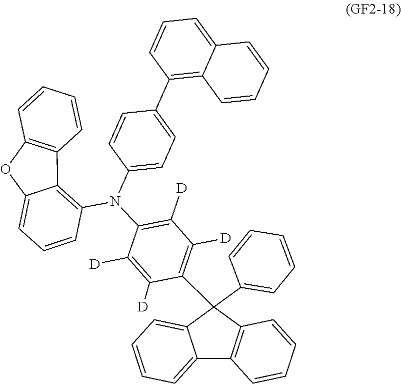 [SMILES: [2H]c1c([2H])c(C2(c3ccccc3)c3ccccc3-c3ccccc32)c([2H])c([2H])c1N(c1ccc(-c2cccc3ccccc23)cc1)c1cccc2oc3ccccc3c12]

In some examples, in a case where the deuterium atoms are contained in L₃ and Ar₇ in the structure of the second functional material GF2, and L₃ and Ar₇ are both tetradeuterated phenylene, the structural formula of the second functional material GF2 may be as shown in the following.

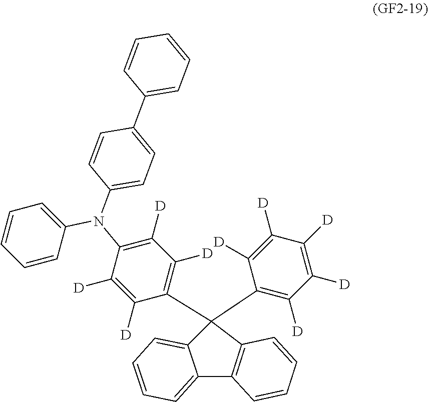 [SMILES: [2H]c1c([2H])c([2H])c(C2(c3c([2H])c([2H])c(N(c4ccccc4)c4ccc(-c5ccccc5)cc4)c([2H])c3[2H])c3ccccc3-c3ccccc32)c([2H])c1[2H]]

In some examples, in a case where the deuterium atoms are contained in L₃ and Ar₅ in the structure of the second functional material GF2, L₃ is tetradeuterated phenylene, Ar₅ is

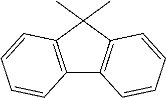

(containing six deuterium atoms), and Ar₇ is phenyl, the structural formula of the second functional material GF2 may be as shown in the following.

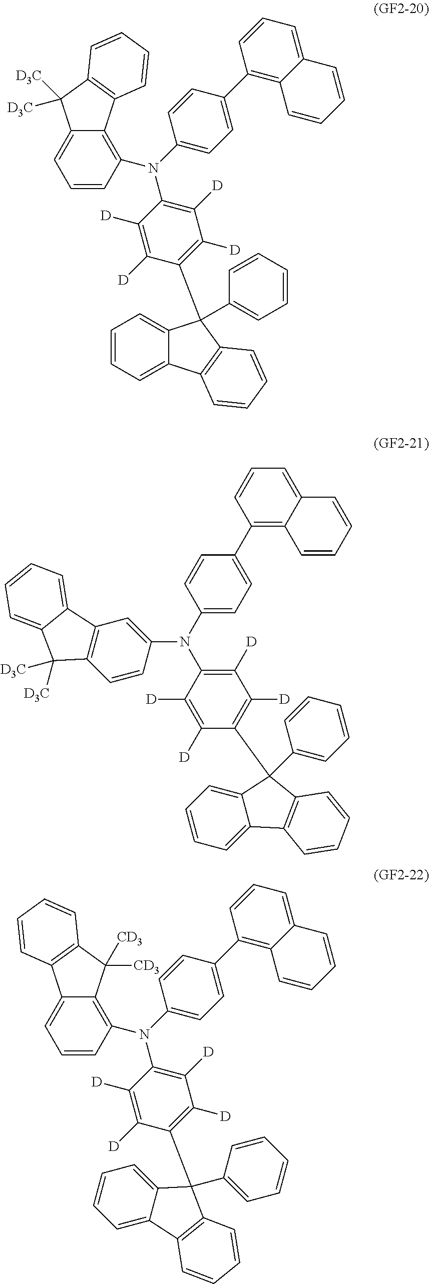

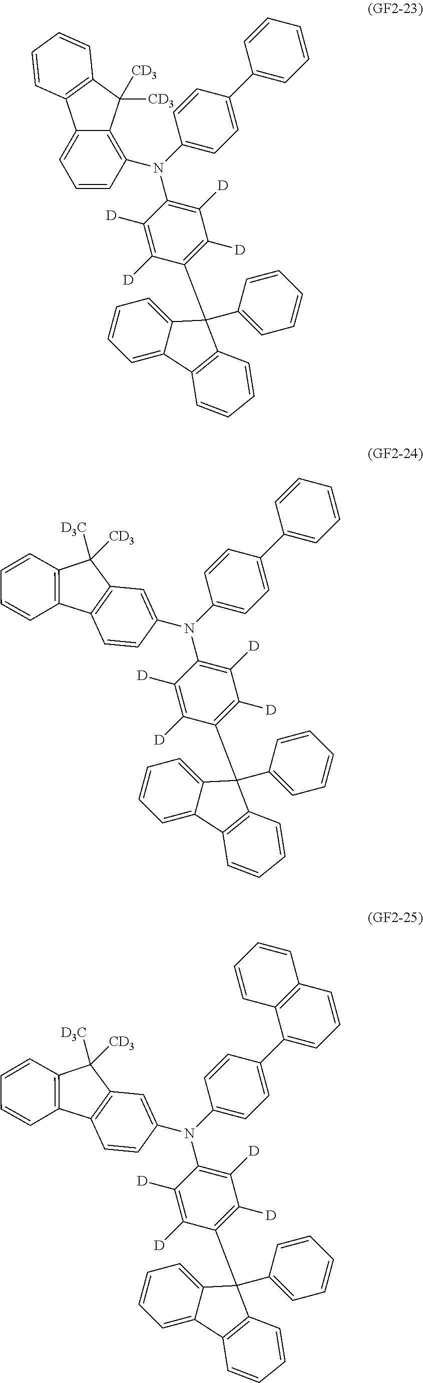 [SMILES: [2H]c1c([2H])c(C2(c3ccccc3)c3ccccc3-c3ccccc32)c([2H])c([2H])c1N(c1ccc(-c2ccccc2)cc1)c1cccc2c1C(C([2H])([2H])[2H])(C([2H])([2H])[2H])c1ccccc1-2 ; [2H]c1c([2H])c(C2(c3ccccc3)c3ccccc3-c3ccccc32)c([2H])c([2H])c1N(c1ccc(-c2ccccc2)cc1)c1ccc2c(c1)C(C([2H])([2H])[2H])(C([2H])([2H])[2H])c1ccccc1-2 ; [2H]c1c([2H])c(C2(c3ccccc3)c3ccccc3-c3ccccc32)c([2H])c([2H])c1N(c1ccc(-c2cccc3ccccc23)cc1)c1ccc2c(c1)C(C([2H])([2H])[2H])(C([2H])([2H])[2H])c1ccccc1-2]

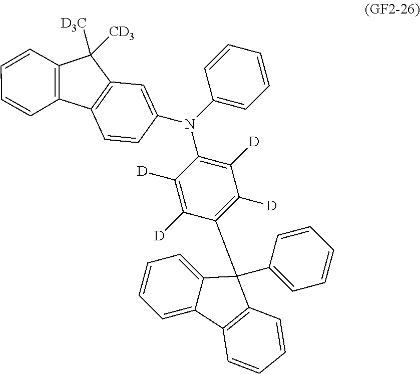 [SMILES: [2H]c1c([2H])c(C2(c3ccccc3)c3ccccc3-c3ccccc32)c([2H])c([2H])c1N(c1ccccc1)c1ccc2c(c1)C(C([2H])([2H])[2H])(C([2H])([2H])[2H])c1ccccc1-2]

It will be noted that, the term “(GF2-x)” in the above structural formulas is an alternative name of each structural formula and is not part of the structure of the structural formula, where x is a positive integer.

The structure of the material (i.e., the second functional material GF2) of the electron blocking layer 1333 is described above, and a position of the electron blocking layer 1333 in the light-emitting device 10 will be described below.

In some embodiments, as shown in FIG. 4, the electron blocking layer 1333 is located on a side of the auxiliary functional layer 1334 away from the light-emitting layer 131 and is configured to block electrons.

From the above description, it can be seen that the first functional material GF1 contains a phenanthroline group, so that the electron stability of the first functional material GF1 is higher than the second functional material GF2. Therefore, the first functional material GF1 may be disposed at a position in the first-type functional layer 133 that is easily attacked by electrons to achieve the function of blocking electrons. It will be understood that, the electrons in the light-emitting device 10 migrate from the cathode 12 to the light-emitting layer 131, and some of the electrons migrate from the light-emitting layer 131 to the first-type functional layer 133; with the arrangement in which the electron blocking layer 1333 is disposed on the side of the auxiliary functional layer 1334 away from the light-emitting layer 131, the auxiliary functional layer 1334 may be closer to the light-emitting layer 131; thus, the first functional material GF1 of the auxiliary functional layer 1334 may block electrons to reduce the amount of electrons in other film layers of the first-type functional layer 133, which may prevent the materials of other film layers in the first-type functional layer 133 from cracking due to electron attack, so that the stability of the light-emitting device 10 may be improved and the service life of the light-emitting device 10 is prolonged.

For example, as shown in FIG. 4, the electron blocking layer 1333 is located on the side of the auxiliary functional layer 1334 away from the light-emitting layer 131 and in direct contact with the auxiliary functional layer 1334.

In some embodiments, the first-type functional layer 133 further includes a hole transport layer 1332 stacked with the electron blocking layer 1333, a material of the hole transport layer 1332 includes a third functional material GF3, and the third functional material GF3 is selected from any one of the structures represented by the following general formula (III).

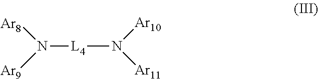

In the above general formula, L₄ is selected from any one of substituted or unsubstituted C3-C30 arylene and substituted or unsubstituted C3-C30 heteroarylene.

Ar₈, Ar₉, Ar₁₀ and Ar₁₁ are the same or different, and are independently selected from any one of substituted or unsubstituted C6-C39 aryl, substituted or unsubstituted C5-C60 heteroaryl, substituted or unsubstituted C6-C60 aryloxy, substituted or unsubstituted C1-C39 alkoxy, substituted or unsubstituted C6-C39 arylamine and substituted or unsubstituted C6-C39 arylsilyl.

Regarding the structure represented by the general formula (III), several points need to be explained below.

In a case where Ar₈, Ar₉, Ar₁₀ and Ar₁₁ are independently selected from substituted C6-C39 aryl, substituted C5-C60 heteroaryl, substituted C6-C60 aryloxy, substituted C1-C39 alkoxy, substituted C6-C39 arylamine and substituted C6-C39 arylsilyl, the types of the substituents are not limited here.

For example, the substituents for the C6-C39 aryl, the C5-C60 heteroaryl, the C6-C60 aryloxy, the C1-C39 alkoxy, the C6-C39 arylamine and the C6-C39 arylsilyl are independently hydrogen, deuterium, substituted or unsubstituted C1-C39 alkyl, substituted or unsubstituted C2-C39 alkenyl, substituted or unsubstituted C2-C39 alkynyl, substituted or unsubstituted C1-C39 alkoxy, substituted or unsubstituted C3-C39 cycloalkyl, substituted or unsubstituted C3-C39 heterocycloalkyl, substituted or unsubstituted C1-C39 alkylsilyl, substituted or unsubstituted C1-C39 alkylboryl.

Here, the description of the terms “Cx aryl” and “Cx alkyl” may refer to the above description of the terms “Cx aryl” and “Cx alkyl”; the description of aryl and heteroaryl may refer to the above description of aryl and heteroaryl; the description of arylene and heteroarylene may refer to the above description of arylene and heteroarylene, and details will not be repeated here.

Based on the above structures of the third functional material GF3, the third functional material GF3, the second functional material GF2 and the first functional material GF1 have matching energy levels and migration rates. In this way, in the case where the auxiliary functional layer 1334 containing the first functional material GF1, the electron blocking layer 1333 containing the second functional material GF2, and the hole transport layer 1332 containing the third functional material GF3 are stacked, a cooperation of the first functional material GF1, the second functional material GF2 and the third functional material GF3 are used in combination to facilitate the transport of holes in the first-type functional layer 133.

In some embodiments, for Ar₈, Ar₉, Ar₁₀ and Ar₁₁, at least one is different from the other three.

It will be understood that, in the case where at least one of Ar₈, Ar₉, Ar₁₀ and Ar₁₁ is different from the other three, the structural formula of the third functional material GF3 has an asymmetric structure, which may increase the glass transition temperature of the third functional material GF3 in comparison with the case where Ar₈, Ar₉, Ar₁₀ and Ar₁₁ are the same and form a symmetric structure, thereby improving the thermal stability of the material and prolonging the service life of the light-emitting device 10.

It will be noted that, at least one of Ar₈, Ar₉, Ar₁₀ and Ar₁₁ is different from the other three, which means that among Ar₈, Ar₉, Ar₁₀ and Ar₁₁, the number of groups having the same structure is less than or equal to three.

The structure of the third functional material GF3 of the structure represented by the general formula (III) will be described below.

In some examples, in a case where L₄ is biphenylene, and three of Ar₈, Ar₉, Ar₁₀ and Ar₁₁ are phenyl, the structural formula of the third functional material GF3 may be as shown in the following.

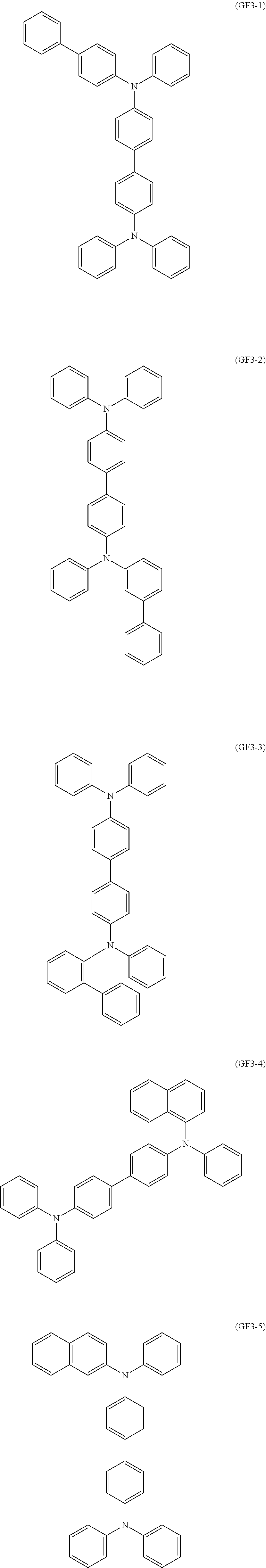 [SMILES: c1ccc(-c2ccc(N(c3ccccc3)c3ccc(-c4ccc(N(c5ccccc5)c5ccccc5)cc4)cc3)cc2)cc1 ; c1ccc(-c2cccc(N(c3ccccc3)c3ccc(-c4ccc(N(c5ccccc5)c5ccccc5)cc4)cc3)c2)cc1 ; c1ccc(-c2ccccc2N(c2ccccc2)c2ccc(-c3ccc(N(c4ccccc4)c4ccccc4)cc3)cc2)cc1 ; c1ccc(N(c2ccccc2)c2ccc(-c3ccc(N(c4ccccc4)c4cccc5ccccc45)cc3)cc2)cc1 ; c1ccc(N(c2ccccc2)c2ccc(-c3ccc(N(c4ccccc4)c4ccc5ccccc5c4)cc3)cc2)cc1]

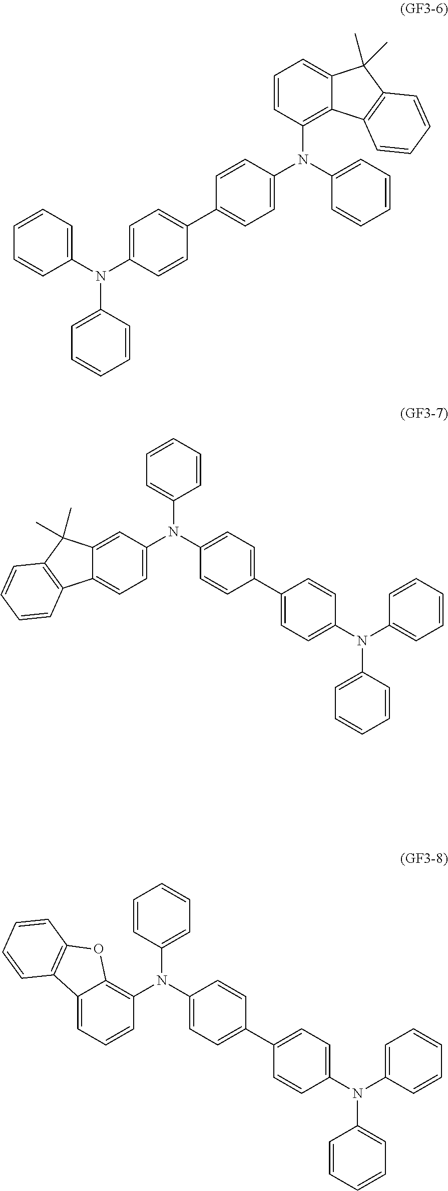 [SMILES: CC1(C)c2ccccc2-c2c(N(c3ccccc3)c3ccc(-c4ccc(N(c5ccccc5)c5ccccc5)cc4)cc3)cccc21 ; CC1(C)c2ccccc2-c2ccc(N(c3ccccc3)c3ccc(-c4ccc(N(c5ccccc5)c5ccccc5)cc4)cc3)cc21 ; c1ccc(N(c2ccccc2)c2ccc(-c3ccc(N(c4ccccc4)c4cccc5c4oc4ccccc45)cc3)cc2)cc1]

In some examples, in a case where L₄ is biphenylene, two of Ar₈, Ar₉, Ar₁₀ and Ar₁₁ are phenyl, and the two phenyl groups are respectively linked to different nitrogen atoms, the structural formula of the third functional material GF3 may be as shown in the following.

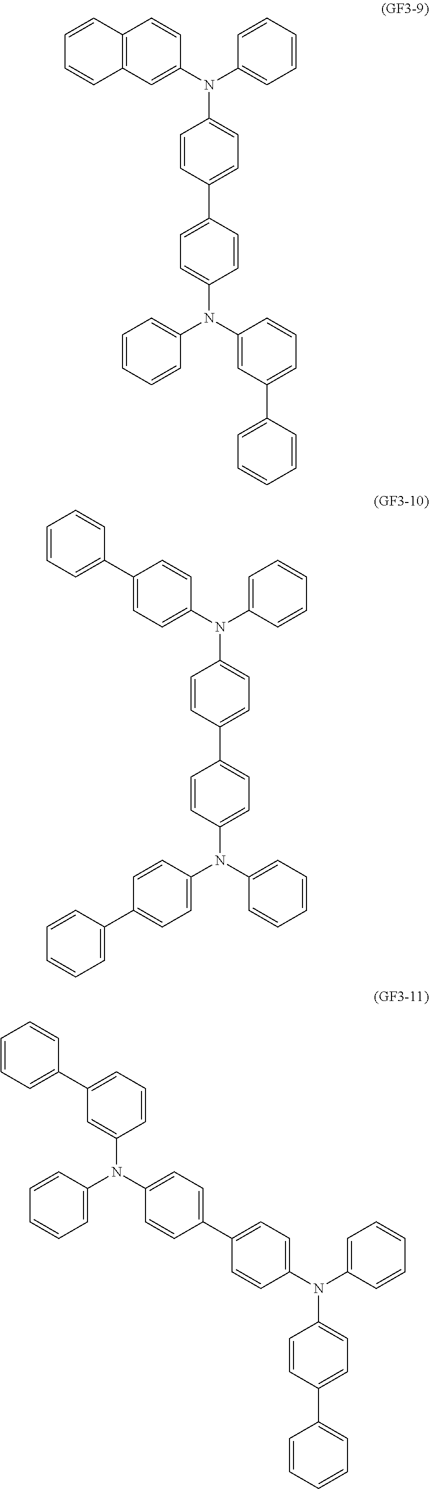 [SMILES: c1ccc(-c2cccc(N(c3ccccc3)c3ccc(-c4ccc(N(c5ccccc5)c5ccc6ccccc6c5)cc4)cc3)c2)cc1 ; c1ccc(-c2ccc(N(c3ccccc3)c3ccc(-c4ccc(N(c5ccccc5)c5ccc(-c6ccccc6)cc5)cc4)cc3)cc2)cc1 ; c1ccc(-c2ccc(N(c3ccccc3)c3ccc(-c4ccc(N(c5ccccc5)c5cccc(-c6ccccc6)c5)cc4)cc3)cc2)cc1]

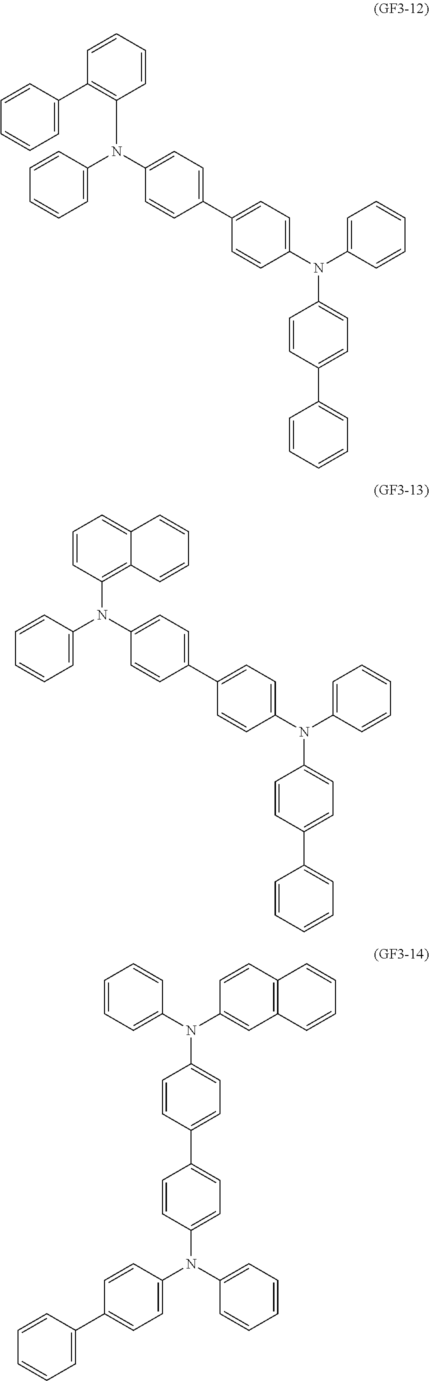

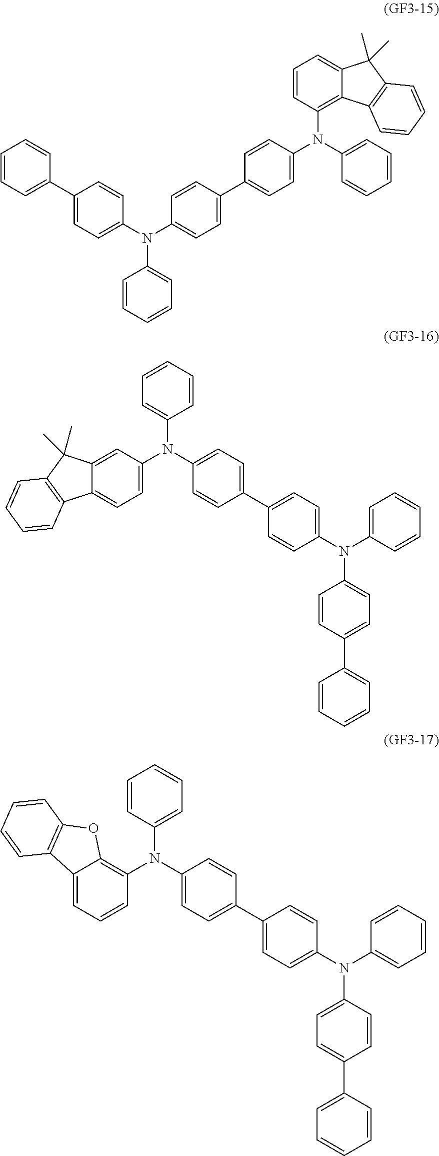 [SMILES: CC1(C)c2ccccc2-c2c(N(c3ccccc3)c3ccc(-c4ccc(N(c5ccccc5)c5ccc(-c6ccccc6)cc5)cc4)cc3)cccc21 ; CC1(C)c2ccccc2-c2ccc(N(c3ccccc3)c3ccc(-c4ccc(N(c5ccccc5)c5ccc(-c6ccccc6)cc5)cc4)cc3)cc21 ; c1ccc(-c2ccc(N(c3ccccc3)c3ccc(-c4ccc(N(c5ccccc5)c5cccc6c5oc5ccccc56)cc4)cc3)cc2)cc1]

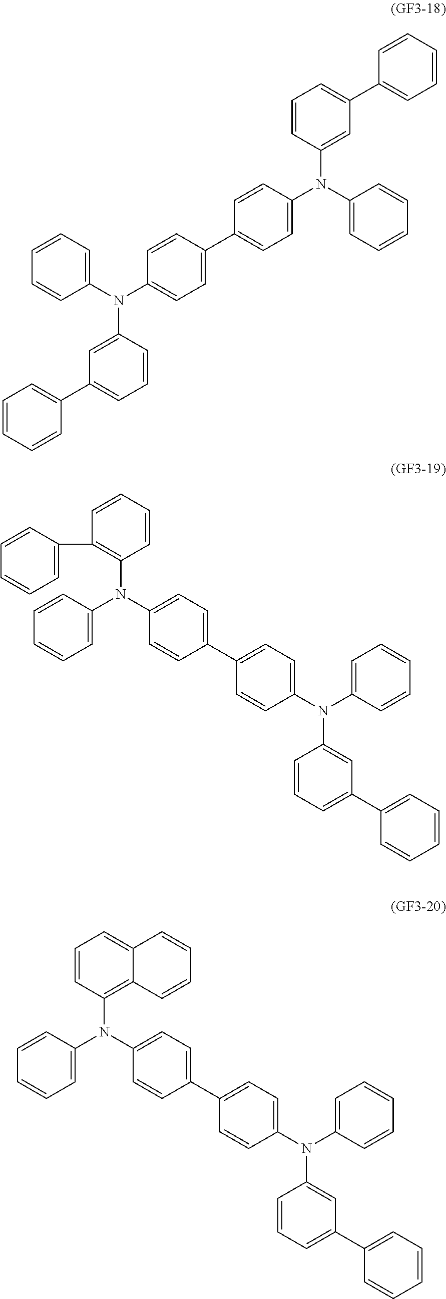 [SMILES: c1ccc(-c2cccc(N(c3ccccc3)c3ccc(-c4ccc(N(c5ccccc5)c5cccc(-c6ccccc6)c5)cc4)cc3)c2)cc1 ; c1ccc(-c2cccc(N(c3ccccc3)c3ccc(-c4ccc(N(c5ccccc5)c5ccccc5-c5ccccc5)cc4)cc3)c2)cc1 ; c1ccc(-c2cccc(N(c3ccccc3)c3ccc(-c4ccc(N(c5ccccc5)c5cccc6ccccc56)cc4)cc3)c2)cc1]

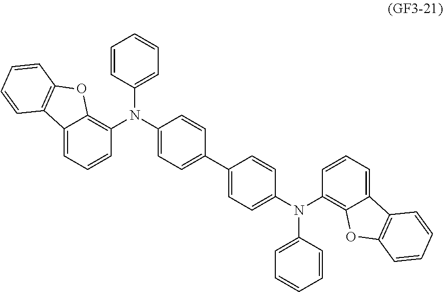 [SMILES: c1ccc(N(c2ccc(-c3ccc(N(c4ccccc4)c4cccc5c4oc4ccccc45)cc3)cc2)c2cccc3c2oc2ccccc23)cc1]

In some examples, in a case where L₄ is biphenylene, and one of Ar₈, Ar₉, Ar₁₀ and Ar₁₁ is phenyl, the structural formula of the third functional material GF3 may be as shown in the following.

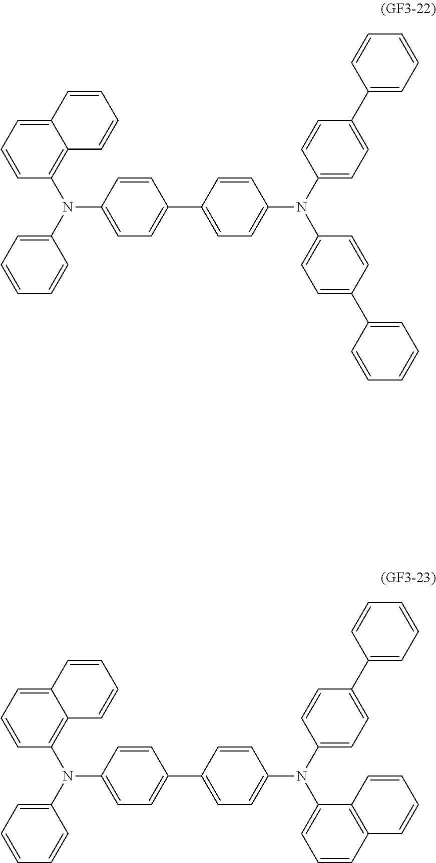 [SMILES: c1ccc(-c2ccc(N(c3ccc(-c4ccccc4)cc3)c3ccc(-c4ccc(N(c5ccccc5)c5cccc6ccccc56)cc4)cc3)cc2)cc1 ; c1ccc(-c2ccc(N(c3ccc(-c4ccc(N(c5ccccc5)c5cccc6ccccc56)cc4)cc3)c3cccc4ccccc34)cc2)cc1]

In some examples, in a case where L₄ is phenanthrylene, and one of Ar₈, Ar₉, Ar₁₀ and Ar₁₁ is phenyl, the structural formula of the third functional material GF3 may be as shown in the following.

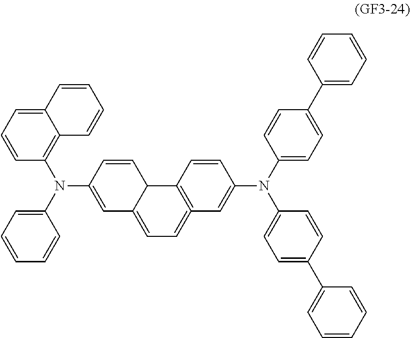

It will be noted that, the term “(GF3-x)” in the above structural formulas is an alternative name of each structural formula and is not part of the structure of the structural formula, where x is a positive integer.

It will be noted that, in the structures represented by the general formula (III), a position of Ar₈, Ar₉, Ar₁₀, or Ar₁₁ to which a nitrogen atom is linked is not limited here.

From the third functional material GF3 represented by any of the above structural formulas (GF3-1) to (GF3-3), (GF3-9) to (GF3-20), and (GF3-22) to (GF3-24), it can be seen that in the structures represented by the general formula (III), in a case where Ar₈, Ar₉, Ar₁₀ or Ar₁₁ is biphenyl, a position of

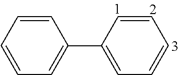

(i.e., biphenyl) to which a nitrogen atom is linked is not limited here. For example, as shown in the structural formulas (GF3-3), (GF3-12), and (GF3-19), a nitrogen atom is linked to the 1-position carbon atom of biphenyl; alternatively, as shown in the structural formulas (GF3-2), (GF3-9), (GF3-11), (GF3-18), (GF3-19), and (GF3-20), a nitrogen atom is linked to the 2-position carbon atom of biphenyl; alternatively, as shown in the structural formulas (GF3-1), (GF3-10) to (GF3-17), and (GF3-22) to (GF3-24), a nitrogen atom is linked to the 3-position carbon atom of biphenyl.

From the third functional materials GF3 represented by any of the above structural formulas (GF3-4), (GF3-5), (GF3-9), (GF3-13), (GF3-14), (GF3-20), (GF3-23) and (GF3-24), it can be seen that in the structures represented by the general formula (III), in a case where Ar₈, Ar₉, Ar₁₀ or Ar₁₁ is

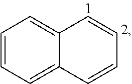

a position of

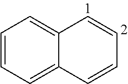

to which a nitrogen atom is linked is not limited here. For example, as shown in the structural formulas (GF3-4), (GF3-13), (GF3-20), (GF3-23), and (GF3-24), a nitrogen atom is linked to the 1-position carbon atom; alternatively, as shown in the structural formulas (GF3-9), (GF3-14), and (GF3-5), a nitrogen atom is linked to the 2-position carbon atom.

From the third functional materials GF3 represented by any of the above structural formulas (GF3-6), (GF3-7), (GF3-15) and (GF3-16), it can be seen that in the structures represented by the general formula (III), in a case where Ar₈, Ar₉, Ar₁₀ or Ar₁₁ is

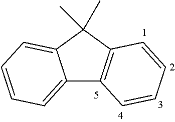

a position of

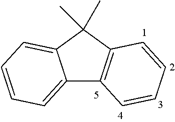

to which a nitrogen atom is linked is not limited here. For examples, as shown in the structural formulas (GF3-7) and (GF3-16), a nitrogen atom is linked to the 2-position carbon atom; alternatively, as shown in the structural formulas (GF3-6) and (GF3-15), a nitrogen atom is linked to the 4-position carbon atom.

In order to improve the molecular stability of the third functional material GF3, in some embodiments, at least one of Ar₈, Ar₉, Ar₁₀, Ar₁₁ and L₄ contains a deuterium atom.

Since the atomic weight of deuterium is twice that of hydrogen, with the provision of at least one deuterium atom contained in the structure represented by the general formula (III), the physical properties of the third functional material GF3 changes; in particular, an atom in the structure formula of the third functional material GF3 is substituted with a deuterium atom, it is possible to effectively suppress molecular vibration, reduce bond length and increase bond energy, thereby improving the molecular stability. Thus, the stability of the third functional material GF3 is improved.

It will be noted that, at least one of Ar₈, Ar₉, Ar₁₀, Ar₁₁ and L₄ contains a deuterium atom, which means that the structure represented by the general formula (III) satisfies at least one of the following two conditions: (1) L₄ is selected from one of deuterated arylene and deuterated heteroarylene; (2) at least one of Ar₈, Ar₉, Ar₁₀ and Ar₁₁ is one of deuterated aryl, deuterated heteroaryl, deuterated aryloxy, deuterated alkoxy, deuterated arylamine and deuterated arylsilyl.

The structure of the third functional material GF3 will be described below in the case where at least one of Ar₈, Ar₉, Ar₁₀, Ar₁₁ and L₄ contains a deuterium atom.

In some examples, in a case where the deuterium atoms are contained in one of Ar₈, Ar₉, Ar₁₀ and Ar₁₁ in the structure of the third functional material GF3, and the deuterated substituent is

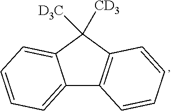 [SMILES: [2H]C([2H])([2H])C1(C([2H])([2H])[2H])c2ccccc2-c2ccccc21]

the structural formula of the third functional material GF3 may be as shown in the following.

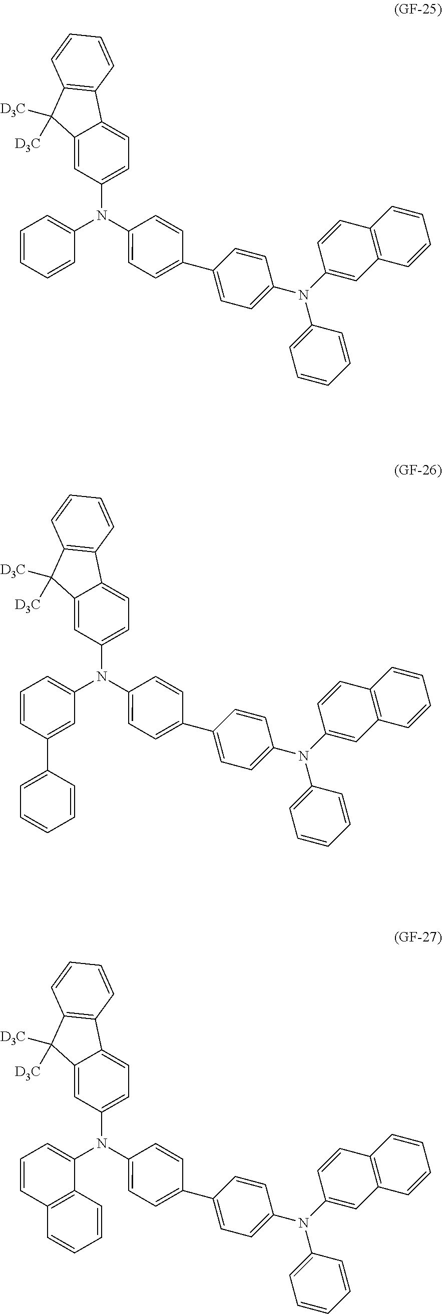 [SMILES: [2H]C([2H])([2H])C1(C([2H])([2H])[2H])c2ccccc2-c2ccc(N(c3ccccc3)c3ccc(-c4ccc(N(c5ccccc5)c5ccc6ccccc6c5)cc4)cc3)cc21 ; [2H]C([2H])([2H])C1(C([2H])([2H])[2H])c2ccccc2-c2ccc(N(c3ccc(-c4ccc(N(c5ccccc5)c5ccc6ccccc6c5)cc4)cc3)c3cccc(-c4ccccc4)c3)cc21 ; [2H]C([2H])([2H])C1(C([2H])([2H])[2H])c2ccccc2-c2ccc(N(c3ccc(-c4ccc(N(c5ccccc5)c5ccc6ccccc6c5)cc4)cc3)c3cccc4ccccc34)cc21]

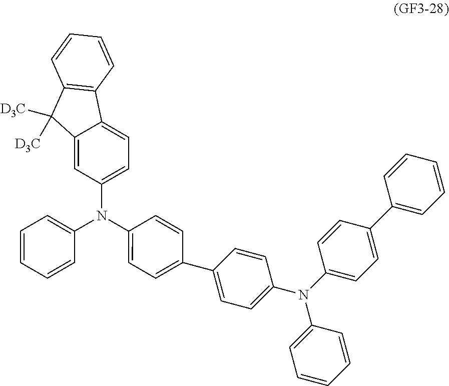 [SMILES: [2H]C([2H])([2H])C1(C([2H])([2H])[2H])c2ccccc2-c2ccc(N(c3ccccc3)c3ccc(-c4ccc(N(c5ccccc5)c5ccc(-c6ccccc6)cc5)cc4)cc3)cc21]

In some examples, in the structure of the third functional material GF3, in a case where L₄ is tetradeuterated biphenyl and one of Ar₈, Ar₉, Ar₁₀ and Ar₁₁ is

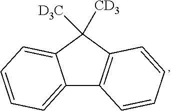 [SMILES: [2H]C([2H])([2H])C1(C([2H])([2H])[2H])c2ccccc2-c2ccccc21]

i.e., the deuterium atoms are contained in L₄ and one of Ar₈, Ar₉, Ar₁₀, and Arm in the structure of the third functional material GF3, the structural formula of the third functional material GF3 may be as shown in the following.

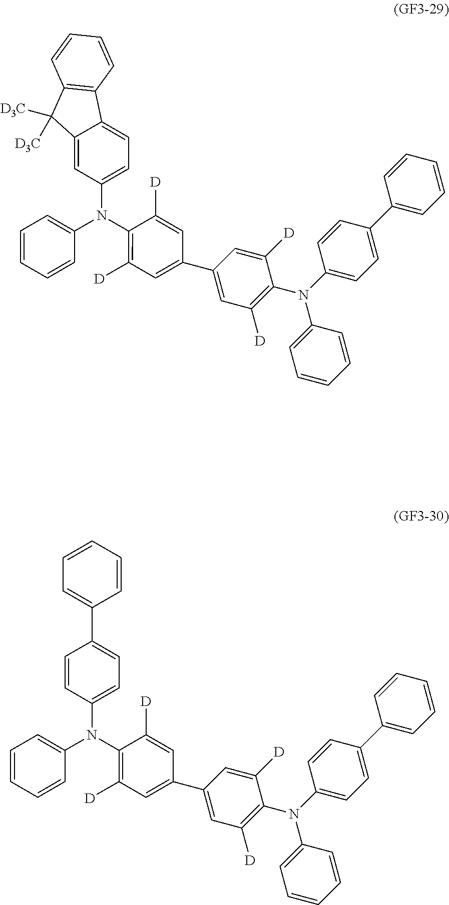 [SMILES: [2H]c1cc(-c2cc([2H])c(N(c3ccccc3)c3ccc4c(c3)C(C([2H])([2H])[2H])(C([2H])([2H])[2H])c3ccccc3-4)c([2H])c2)cc([2H])c1N(c1ccccc1)c1ccc(-c2ccccc2)cc1 ; [2H]c1cc(-c2cc([2H])c(N(c3ccccc3)c3ccc(-c4ccccc4)cc3)c([2H])c2)cc([2H])c1N(c1ccccc1)c1ccc(-c2ccccc2)cc1]

It will be noted that, the term “(GF3-x)” in the above structural formulas is an alternative name of each structural formula and is not part of the structure of the structural formula, where x is a positive integer.

In some embodiments, as shown in FIG. 4, the hole transport layer 1332 is located on a side of the electron blocking layer 1333 away from the light-emitting layer 131 and is configured to transport holes.

In the case where the hole transport layer 1332 is located on the side of the electron blocking layer 1333 away from the light-emitting layer 131, the auxiliary functional layer 1334, the electron blocking layer 1333, and the hole transport layer 1332 are sequentially arranged in a direction away from the light-emitting layer 131. Since the third functional material GF3, the second functional material GF2 and the first functional material GF1 have matching energy levels and migration rates, with the arrangement in which the auxiliary functional layer 1334, the electron blocking layer 1333 and the hole transport layer 1332 are sequentially arranged in the direction away from the light-emitting layer 131, holes from the anode 11 may sequentially pass through the hole transport layer 1332, the electron blocking layer 1333 and the auxiliary functional layer 1334 and be injected into the light-emitting layer 131 due to an action of a driving voltage; meanwhile, electrons migrated out from the light-emitting layer 131 would first pass through the auxiliary functional layer 1334, and then enter the electron blocking layer 1333 and the hole transport layer 1332. However, since the electron stability of the first functional material GF1 in the auxiliary functional layer 1334 is high, the auxiliary functional layer 1334 may block the electrons to reduce the amount of electrons in the electron blocking layer 1333 and the hole transport layer 1332, so as to prevent the materials of the electron blocking layer 1333 and the hole transport layer 1332 from cracking due to electron attack, thereby improving the stability of the light-emitting device 10 and prolonging the service life of the light-emitting device 10.

For example, as shown in FIG. 4, the hole transport layer 1332 is located on the side of the electron blocking layer 1333 away from the light-emitting layer 131 and in direct contact with the electron blocking layer 1333.

Synthesis processes for preparing the first functional material GF1 will be introduced below by taking an example in which the first functional material GF1 is represented by the above structural formula (GF1-4).

In the related art, carbon-carbon coupling reaction and carbon-nitrogen coupling reaction are widely used in the synthesis of organic materials. The carbon-carbon coupling reaction is, for example, Suzuki coupling reaction, Negishi coupling reaction, Yamamoto coupling reaction, Grignard coupling reaction, Stille coupling reaction, or Heck coupling reaction. The carbon-nitrogen coupling reaction is, for example, Buchwald coupling reaction, Ullmann coupling, silylation reaction, phosphating reaction, borylation reaction, or polycondensation reaction.

For example, the above reactions are as shown in the following general reaction formulas (A) and (B).

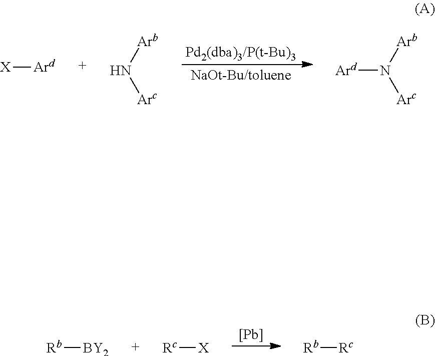

It will be noted that, for the general reaction formula (A), the catalysts are Tris(dibenzylideneacetone) dipalladium (Pd₂(dba)₃), tri-tert-butylphosphine (P(t-Bu)₃) and sodium tert-butoxide (NaOt-Bu), and the reaction solvent is toluene; the catalyst for the general reaction formula (B) is lead (Pb). X is bromine or iodine. Ar^{d}, Ar^{b}, Ar^{c}, R^{b}, and R^{c} are groups that need to be linked through a coupling reaction.

For example, based on the above general reaction formulas (A) and (B), the preparing method of the first functional material (GF1-4) includes steps S1 to S3.

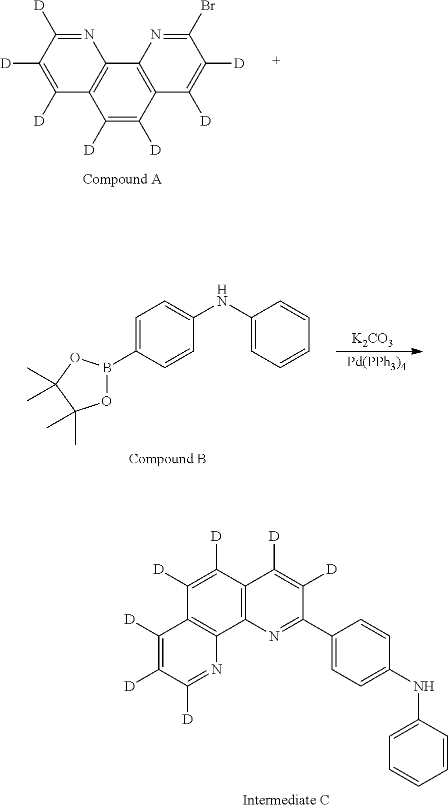

In S1, 20 mmol of Compound A, 12 mmol of Compound B, 1.16 g (1 mmol) of tetrakis(triphenylphosphine) palladium (Pd(PPh₃)₄) and 2.5 g (18 mmol) of potassium carbonate (K₂CO₃) are dissolved in 240 mL of a mixed solution of tetrahydrofuran (THF) and water (H₂O) (a volume ratio of tetrahydrofuran to water is 2:1), and the resulting solution is stirred at 70° C. for 5 hours. The reaction solution is then cooled to room temperature, 160 ml of water is added to the reaction solution, and the resulting solution is extracted three times with 200 mL of diethyl ether. The obtained organic layer is then dried using magnesium sulfate, and the solvent is evaporated to obtain a crude product. The crude product is purified by silica gel column chromatography to obtain Intermediate C in 74% yield.

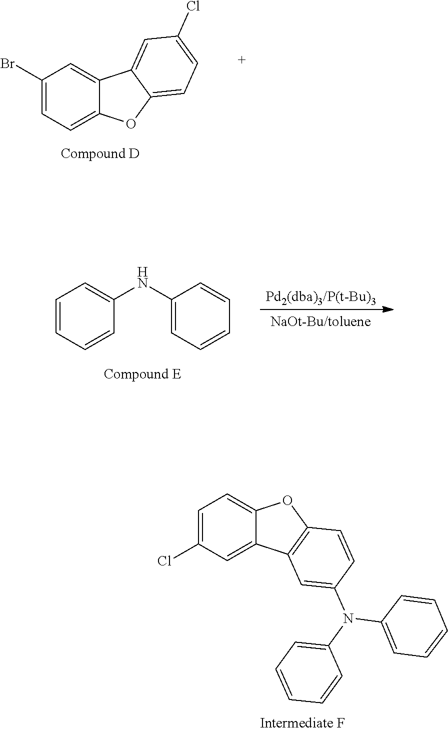 [SMILES: Clc1ccc2oc3ccc(Br)cc3c2c1 ; c1ccc(Nc2ccccc2)cc1 ; Clc1ccc2oc3ccc(N(c4ccccc4)c4ccccc4)cc3c2c1]

In S2, Compound D (15 mmol) and Compound E (17 mmol) are dissolved in 50 mL of toluene, and then catalysts Pd₂(dba)₃ (0.15 mmol), P(t-Bu)₃ (0.8 mmol), and NaOt-Bu (45 mmol) are added under nitrogen atmosphere. After the addition, the reaction temperature is slowly raised to 110° C., and the mixture is stirred for 10 h. Distilled water is then added to the reaction solution and the reaction solution is extracted with ethyl acetate. The extracted organic layer is then dried using magnesium sulfate, and the solvent is removed using a rotary evaporator. The remaining material is purified by column chromatography to obtain Intermediate F in 80% yield.

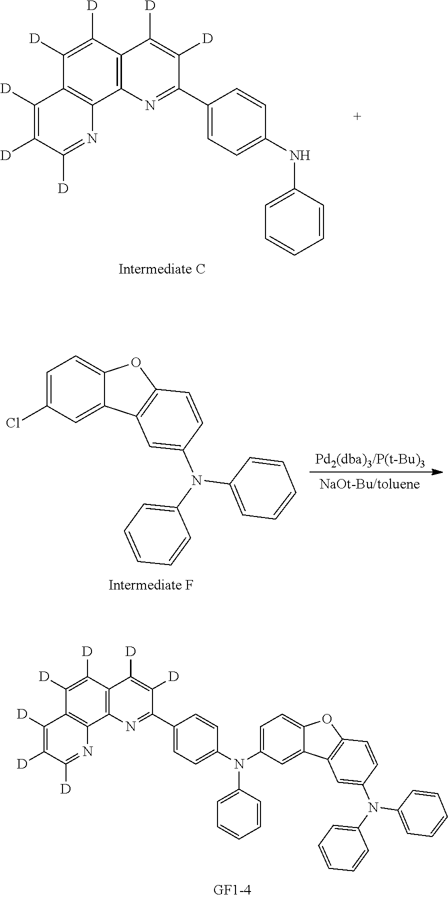 [SMILES: [2H]c1nc2c(c([2H])c1[2H])c([2H])c([2H])c1c([2H])c([2H])c(-c3ccc(Nc4ccccc4)cc3)nc12 ; Clc1ccc2oc3ccc(N(c4ccccc4)c4ccccc4)cc3c2c1 ; [2H]c1nc2c(c([2H])c1[2H])c([2H])c([2H])c1c([2H])c([2H])c(-c3ccc(N(c4ccccc4)c4ccc5oc6ccc(N(c7ccccc7)c7ccccc7)cc6c5c4)cc3)nc12]

In S3, after Intermediate C (15 mmol) and Intermediate F (15 mmol) are dissolved in 50 mL of toluene, catalysts Pd₂(dba)₃ (0.15 mmol), P (t-Bu) 3 (0.8 mmol), and NaOt-Bu (45 mmol) are added under nitrogen atmosphere. After the addition, the reaction temperature is slowly raised to 110° C., and the mixture is stirred for 10 h. Distilled water is then added to the reaction solution and the reaction solution is extracted with ethyl acetate. The extracted organic layer is then dried using magnesium sulfate, and the solvent is removed using a rotary evaporator. The remaining material is purified by column chromatography to obtain the final product (GF1-4) in 75% yield.

The first ionization energies of the first functional material GF1, the second functional material GF2, and the third functional material GF3 will be introduced below.

In some embodiments, the first ionization potential IP(GF1) of the first functional material GF1 is greater than or equal to the first ionization potential IP(GF2) of the second functional material GF2; the first ionization potential IP(GF2) of the second functional material GF2 is greater than or equal to the first ionization potential IP(GF3) of the third functional material GF3.

That is, the first ionization potential IP(GF1) of the first functional material GF1, the first ionization potential IP(GF2) of the second functional material GF2, and the first ionization potential IP(GF3) of the third functional material GF3 satisfy the following relationship: IP(GF1)≥IP(GF2)≥IP(GF3).

It will be understood that, the HOMO energy level difference between the materials of two adjacent layers (i.e., the HOMO energy level difference between the first functional material GF1 and the second functional material GF2, or the HOMO energy level difference between the second functional material GF2 and the third functional material GF3) in the above-mentioned first-type functional layer 133 represents the energy that the external electric field needs to overcome to transport holes. There is a corresponding relationship between the first ionization potential IP and the HOMO energy level. Therefore, with the design of IP(GF1)≥ IP(GF2)≥ IP(GF3), the external electric field required for the transport of holes from the hole transport layer 1332 to the electron blocking layer 1333 and from the electron blocking layer 1333 to the auxiliary functional layer 1334 is small; that is, the voltage for driving the light-emitting device 10 to emit light is low. In this way, the driving voltage of the light-emitting device 10 may be reduced, so that the power consumption of the light-emitting device 10 is reduced.

For example, the first ionization potential IP(GF1) of the first functional material GF1 is equal to the first ionization potential IP(GF2) of the second functional material GF2; the first ionization potential IP(GF2) of the second functional material GF2 is equal to the first ionization potential IP(GF3) of the third functional material GF3.

In some embodiments, a difference between the first ionization potential IP(GF1) of the first functional material GF1 and the first ionization potential IP(GF2) of the second functional material GF2 is less than or equal to 0.2 eV.

That is, the first ionization potential IP(GF1) of the first functional material GF1 and the first ionization potential IP(GF2) of the second functional material GF2 satisfy the following relationship: IP(GF1)−IP(GF2)≤0.2 eV.

With such a design, the external electric field required for the transport of holes from the electron blocking layer 1333 to the auxiliary functional layer 1334 is small, so that the voltage for driving the light-emitting device 10 to emit light is low. In this way, the driving voltage of the light-emitting device 10 may be reduced, thereby reducing the power consumption of the light-emitting device 10.

For example, the difference between the first ionization potential IP(GF1) of the first functional material GF1 and the first ionization potential IP(GF2) of the second functional material GF2 may be 0.2 eV, 0.1 eV, or 0.05 eV.

In some embodiments, a difference between the first ionization potential IP(GF2) of the second functional material GF2 and the first ionization potential IP(GF3) of the third functional material GF3 is less than or equal to 0.2 eV.

That is, the first ionization potential IP(GF2) of the second functional material GF2 and the first ionization potential IP(GF3) of the third functional material GF3 satisfy the following relationship: IP(GF2)−IP(GF3)≤0.2 eV.

With such a design, the external electric field required for the transport of holes from the hole transport layer 1332 to the electron blocking layer 1333 is small, so that the voltage for driving the light-emitting device 10 to emit light is low. In this way, the driving voltage of the light-emitting device 10 may be reduced, thereby reducing the power consumption of the light-emitting device 10.

For example, the difference between the first ionization potential IP(GF2) of the second functional material GF2 and the first ionization potential IP(GF3) of the third functional material GF3 may be 0.2 eV, 0.1 eV, or 0.05 eV.

In some embodiments, a difference between the first ionization potential IP(GF1) of the first functional material GF1 and the first ionization potential IP(GF3) of the third functional material GF3 is less than or equal to 0.3 eV.

That is, the first ionization potential IP(GF1) of the first functional material GF1 and the first ionization potential IP(GF3) of the third functional material GF3 satisfy the following relationship: IP(GF1)−IP(GF3)≤0.3 eV.

With such a design, the external electric field required for the transport of holes from the hole transport layer 1332 to the auxiliary functional layer 1334 is small, so that the voltage for driving the light-emitting device 10 to emit light is low. In this way, the driving voltage of the light-emitting device 10 may be reduced, thereby reducing the power consumption of the light-emitting device 10.

For example, the difference between the first ionization potential IP(GF1) of the first functional material GF1 and the first ionization potential IP(GF3) of the third functional material GF3 may be 0.3 eV, 0.2 eV, or 0.1 eV.

Thicknesses of the auxiliary functional layer 1334, the electron blocking layer 1333, and the hole transport layer 1332 will be introduced below.

In some embodiments, as shown in FIG. 4, a thickness d2 of the electron blocking layer 1333 is greater than or equal to a thickness d1 of the auxiliary functional layer 1334. That is, d2≥d1.

With the design of d2≥d1, the thickness d1 of the auxiliary functional layer 1334 may be relatively small, so that holes may be effectively injected and the light emission efficiency may be improved.

In some embodiments, as shown in FIG. 4, the thickness d1 of the auxiliary functional layer 1334 is in a range of 5 nm to 50 nm.

With such a design, the thickness d1 of the auxiliary functional layer 1334 is relatively small, so that the holes may be effectively injected to facilitate the balance between electrons and holes during the light emission process. Thus, the light emission efficiency may be improved.

For example, the thickness d1 of the auxiliary functional layer 1334 may be 5 nm, 10 nm, 20 nm, 30 nm, 40 nm, or 50 nm.

In some embodiments, as shown in FIG. 4, the thickness d2 of the electron blocking layer 1333 is in a range of 10 nm to 55 nm.

With such a design, the thickness d2 of the electron blocking layer 1333 is reasonable such that electrons may be effectively blocked while holes may be effectively injected.

For example, the thickness d2 of the electron blocking layer 1333 may be 10 nm, 20 nm, 30 nm, 40 nm, 50 nm, or 55 nm.

In some embodiments, as shown in FIG. 4, a thickness d3 of the hole transport layer 1332 is in a range of 50 nm to 200 nm.

Since the hole transport layer 1332 has good performance in hole transport, with the design in which the thickness d3 of the hole transport layer 1332 is in the range of 50 nm 200 nm, the thickness d3 of the hole transport layer 1332 is relatively great, which facilitates the effective hole injection and the balance between electrons and holes during the light emission process, thereby improving the light emission efficiency.

For example, the thickness d3 of the hole transport layer 1332 may be 50 nm, 70 nm, 80 nm, 100 nm, 150 nm, or 200 nm.

In some embodiments, in the case where the charge generating layer 14 includes the electron generating layer 141 and the hole generating layer 142 that are stacked, a material of the hole generating layer 142 includes the third functional material GF3.

As shown in FIG. 8, in some implementations, the hole generating layer 142 is stacked with and in direct contact with a hole transport layer 1332 of a light-emitting unit 13 adjacent to the hole generating layer 142. In this case, with the design in which the material of the hole generating layer 142 includes the third functional material GF3, both the hole generating layer 142 and the hole transport layer 1332 contain the third functional material GF3, so that the materials of the two film layers match well, which facilitates the effective hole injection to improve the light emission efficiency.

For example, the material of the hole generating layer 142 includes the third functional material GF3 and a P-type dopant.

In some embodiments, as shown in FIGS. 3, 4 and 8, the first-type functional layer 133 further includes the hole injection layer 1331 (e.g., the first-type functional layer 133a in FIG. 8 includes the hole injection layer 1331a), and the hole injection layer 1331 is located on a side of the hole transport layer 1332 away from the electron blocking layer 1333 (e.g., as shown in FIG. 8, the hole injection layer 1331a is located on a side of the hole transport layer 1332a away from the electron blocking layer 1333a); a material of the hole injection layer 1331 includes the third functional material GF3.

The hole injection layer 1331 may be configured to reduce the hole injection barrier to improve the hole injection efficiency. As shown in FIG. 8, the hole injection layer 1331 is stacked with and in direct contact with the adjacent hole transport layer 1332 of the light-emitting unit 13 (e.g., the hole injection layer 1331a is adjacent to the hole transport layer 1332a). With the design in which the hole injection layer 1331 includes the third functional material GF3, both the hole injection layer 1331 and the hole transport layer 1332 contain the third functional material GF3, so that the materials of the two film layers match well, which facilitates the effective hole injection and improves the light emission efficiency.

For example, a material of the hole injection layer 1331 includes the third functional material GF3 and a P-type dopant.

The structures and materials of various film layers in the light-emitting device 10 including the first-type functional layer 133 are described above, and it can be seen from the above that some embodiments of the present disclosure may achieve the objective of improving the stability of the light-emitting device 10. Another effect that may be achieved in the case where the first functional material GF1, the second functional material GF2, and the third functional material GF3 are applied to the first-type functional layer 133 in combination will be introduced below.

In some implementations, in order to increase the injection of holes, a P-type dopant (P-doping material) is added into the electron blocking layer 1333 of the OLED light-emitting device 10. However, with such a design, lateral current leakage will occur and result in a color cross-talk phenomenon; that is, when the blue light-emitting device 103 is lit, the green light-emitting device 102 also emits light, which results in poor color purity, a serious color mixing problem, and a poor display effect of the OLED light-emitting device 10. With a design in which no P-type dopant is added into the electron blocking layer 1333 of the green light-emitting device 102, the problem of lateral current leakage is solved, but the power consumption of the green light-emitting device 102 increases.

In some embodiments, a light-emitting layer 131 of each light-emitting unit 13 of the at least two light-emitting units 13 is configured to emit green light. In this case, the light-emitting device 10 is a green light-emitting device 102.

With a design in which the first functional material GF1, the second functional material GF2 and the third functional material GF3 are applied in the first-type functional layer 133 of the green light-emitting device 102 in combination, and the auxiliary functional layer 1334 containing the first functional material GF1, the electron blocking layer 1333 containing the second functional material GF2 and the hole transport layer 1332 containing the third functional material GF3 are sequentially arranged in the direction away from the light-emitting layer 131, the lateral current may be reduced to avoid the color cross-talk due to the lateral current leakage between the blue light-emitting device 103 and the green light-emitting device 102, thereby improving the display effect of the OLED display panel 100.

In order to objectively appraise the technical effects of the embodiments of the present disclosure, technical solutions provided in some embodiments of the present disclosure will be exemplarily described in detail below with the following experimental examples and comparative examples.

In the following embodiments, reorganization energies (ROE) of the first functional material GF1 and the second functional material GF2 and first ionization potentials (IP) of the first functional material GF1 and the second functional material GF2 are measured and compared.

In the following embodiments, the calculation method of reorganization energy (ROE) is the same, and the calculation method of first ionization potential (IP) is the same; both ROE and IP are calculated using the molecular computational and modeling software Spartan, and the calculation conditions are: DFT, B3LYP, 6-31g**. Calculation results are as shown in Table 1 below.

TABLE 1

| Compound | ROE | IP |
|---|---|---|
| GF1-4 | 0.13 | 4.89 |
| GF 1-10 | 0.14 | 4.88 |
| GF 1-1 | 0.13 | 4.82 |
| GF 1-2 | 0.18 | 4.80 |
| GF 2-15 | 0.13 | 4.78 |
| GF 2-20 | 0.16 | 4.79 |
| GF 2-24 | 0.15 | 4.77 |
| GF 2-6 | 0.15 | 4.78 |

It will be noted that, the unit of reorganization energy (ROE) and the unit of first ionization potential (IP) in Table 1 are all electron volt, and the symbol is eV. As for the structural formulas represented by “GF1-x”, “GF2-x” and “GF3-x” (x is a positive integer), reference is made to the above description, and details will not be repeated here.

It can be seen from Table 1 that, the reorganization energies of the four types of first functional materials GF1 are all in a range of 0.13 eV to 0.18 eV, and the reorganization energies of the four types of second functional materials GF2 are all in a range of 0.13 eV to 0.16 eV, which represents that both the first functional material GF1 and the second functional material GF2 have good performance in hole transport.

It can be seen from Table 1 that, the first ionization potentials of the four types of first functional materials GF1 are all in a range of 4.80 eV to 4.89 eV, and the first ionization potentials of the four types of second functional materials GF2 are all in a range of 4.77 eV to 4.79 eV; the first ionization potential of the first functional material GF1 is greater than the first ionization potential of the second functional material GF2, and the difference between the two is less than 0.2 eV, which represents that the energy levels of the first functional material GF1 and the second functional material GF2 match. In this way, the external electric field required for the transport of holes from the electron blocking layer 1333 to the auxiliary functional layer 1334 is small; that is, the voltage for driving the light-emitting device 10 to emit light is low. Thus, the driving voltage of the light-emitting device 10 may be reduced, thereby reducing the power consumption of the light-emitting device 10.

In the following experimental examples and comparative examples, the hole injection layers 1331, hole transport layers 1332, electron blocking layers 1333, auxiliary functional layers 1334 and hole generating layers 142 of different light-emitting devices 10 are each made of different materials, and the voltages, light emission efficiency and device life of the light-emitting devices 10 are compared.

In the following comparative examples and experimental examples, the test conditions of the light-emitting devices 10 are the same.

As shown in FIG. 8, each of the light-emitting devices 10 in the following comparative examples and experimental examples includes an anode 11 and a cathode 12 that are oppositely arranged, and two light-emitting units 13 disposed between the cathode 12 and the anode 11; a charge generating layer 14 is provided between the two light-emitting units 13, and the charge generating layer 14 includes an electron generating layer 141 located on a side proximate to the anode 11 and a hole generating layer 142 located on a side proximate to the cathode 12. Each light-emitting unit 13 of the two light-emitting units 13 includes a first-type functional layer 133, a light-emitting layer 131 and a second-type functional layer 132, and the difference between the two light-emitting units 13 is that: in the first light-emitting unit 13a proximate to the anode 11, the first-type functional layer 133a includes a first hole injection layer 1331a, a first hole transport layer 1332a, a first electron blocking layer 1333a, and a first auxiliary functional layer 1334a that are sequentially stacked in a direction away from the anode 11, and the second-type functional layer 132a includes a first hole blocking layer 1323a; in the second light-emitting unit 13b proximate to the cathode 12, the first-type functional layer 133b includes a second hole transport layer 1332b, a second electron blocking layer 1333b, and a second auxiliary functional layer 1334b that are sequentially stacked in the direction away from the anode 11, and the second-type functional layer 132b includes a second hole blocking layer 1323b, a second electron transport layer 1322b, and a second electron injection layer 1321b that are sequentially stacked in the direction away from the anode 11.

In the following comparative examples and experimental examples, thicknesses of the first hole injection layer 1331a, the first hole transport layer 1332a, the first electron blocking layer 1333a, the first auxiliary functional layer 1334a, the light-emitting layer 131a, the first hole blocking layer 1323a, the electron generating layer 141, the hole generating layer 142, the second hole transport layer 1332b, the second electron blocking layer 1333b, the second auxiliary functional layer 1334b, the light-emitting layer 131b, the second hole blocking layer 1323b, the second electron transport layer 1322b, and the second electron injection layer 1321b that are stacked in a direction from the anode 11 to the cathode 12 are 100 Å, 190 Å, 60 Å, 40 Å, 400 Å, 50 Å, 180 Å, 90 Å, 410 Å, 60 Å, 40 Å, 400 Å, 50 Å, 350 Å and 10 Å, respectively.

Materials involved in the above film layers of the light-emitting device 10 include the materials represented by the following structural formulas.

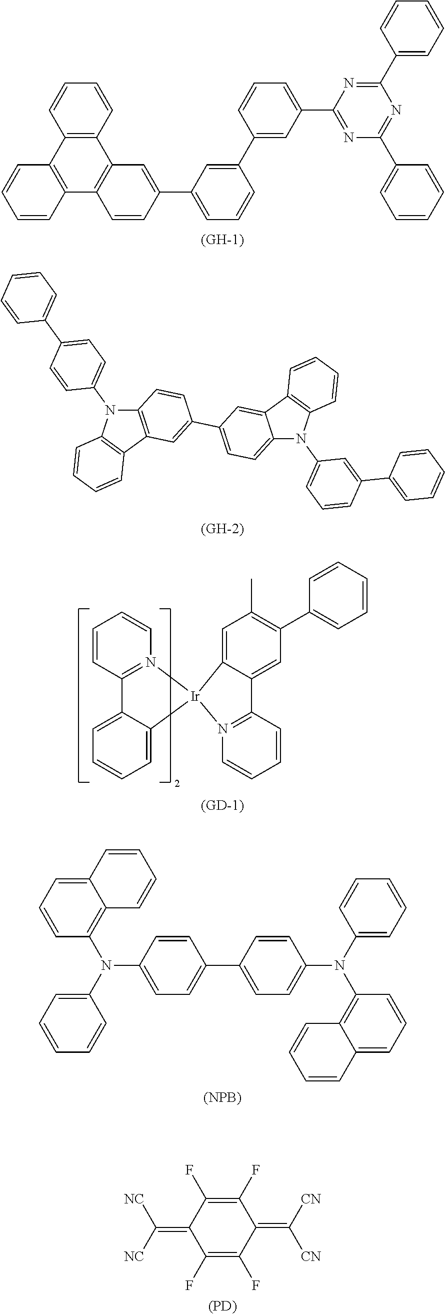

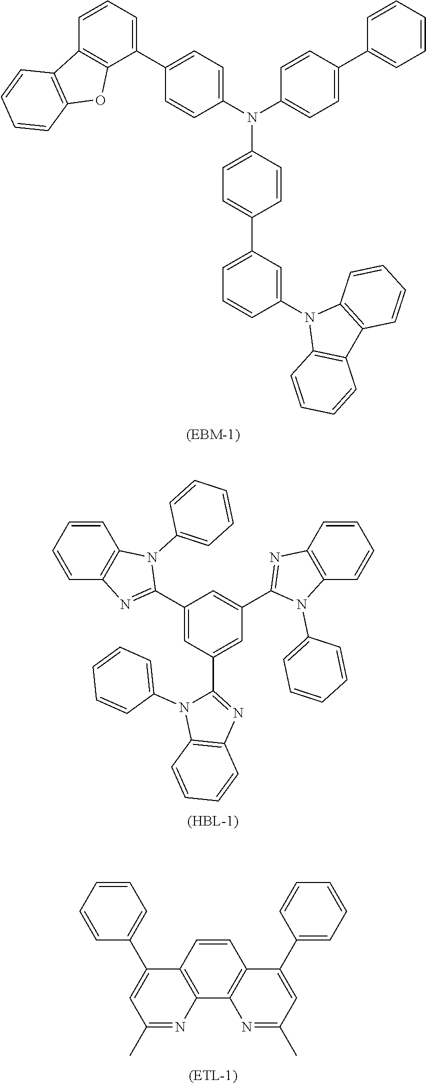 [SMILES: c1ccc(-c2ccc(N(c3ccc(-c4cccc(-n5c6ccccc6c6ccccc65)c4)cc3)c3ccc(-c4cccc5c4oc4ccccc45)cc3)cc2)cc1 ; c1ccc(-n2c(-c3cc(-c4nc5ccccc5n4-c4ccccc4)cc(-c4nc5ccccc5n4-c4ccccc4)c3)nc3ccccc32)cc1 ; Cc1cc(-c2ccccc2)c2ccc3c(-c4ccccc4)cc(C)nc3c2n1]

It will be noted that, (GH-1), (GH-2), (GD-1), (NPB), (PD), (EBM-1), (HBL-1), and (ETL-1) appearing in the above structural formulas are each an alternative name of each structural formula and not part of the structure of structural formula.

Film layers that are made of the same material in the comparative examples and the experimental examples will be described below. In the following comparative examples and experimental examples, a material of the anode 11 is indium tin oxide (ITO); materials of the light-emitting layers 131 of the two light-emitting units 13 are the same, and both include a first host material, a second host material and a first guest material, and a mass ratio of the first host material, the second host material and the first guest material is 45:45:10; the structural formula of the first host material is as shown in the structural formula (GH-1), the structural formula of the second host material is as shown in the structural formula (GH-2), and the structural formula of the first guest material is as shown in the structural formula (GD-1); the structural formulas of the materials of the first hole blocking layer 1323a and the second hole blocking layer 1323b are both as shown in the structural formula (HBL-1); the materials of the electron generating layer 141 and the second electron transport layer 1322b both include an electron transport material and ytterbium, and a mass ratio of the electron transport material to ytterbium is 99:1; the structural formula of the electron transport material is as shown in the structural formula (ETL-1); a material of the second electron injection layer 1321b is ytterbium; and a material of the cathode 12 is a magnesium-silver alloy.

Differences in the materials of the film layers between the comparative examples and the experimental examples will be described below. The film layers that are made of different materials include: the first hole injection layer 1331a, the first hole transport layer 1332a, the first electron blocking layer 1333a, the first auxiliary functional layer 1334a, the hole generating layer 142, the second hole transport layer 1332b, the second electron blocking layer 1333b and the second auxiliary functional layer 1334b. In a same experimental example or a same comparative example, the materials of the hole generating layer 142 and the first hole injection layer 1331a are the same, the materials of the first hole transport layer 1332a and the second hole transport layer 1332b are the same, the materials of the first electron blocking layer 1333a and the second electron blocking layer 1333b are the same, and the materials of the first auxiliary functional layer 1334a and the second auxiliary functional layer 1334b are the same.

In Experimental Examples 1 to 16 and Comparative Examples 1 to 2, the materials of the hole generating layer 142 and the first hole injection layer 1331a both include a hole transport material and a P-type dopant, and a mass ratio of the hole transport material to the P-type dopant is 98:2. The structural formula of the P-type dopant is as shown in the structural formula (PD). In Experimental Examples 1 to 16, the structural formulas of the hole transport material are respectively as shown in structural formulas (GF3-9), (GF3-1), (GF3-2), (GF3-3), (GF3-4), (GF3-5), (GF3-6), (GF3-7), (GF3-10), (GF3-8), (GF3-11), (GF3-12), (GF3-25), (GF3-27), (GF3-28) and (GF3-29). In Comparative Example 1, the structural formula of the hole transport material is as shown in the structural formula (GF3-9). In Comparative Example 2, the structural formula of the hole transport material is as shown in the structural formula (NPB).

In Experimental Examples 1 to 16 and Comparative Example 1, the material of the first hole transport layer 1332a and the material of the second hole transport layer 1332b are both the third functional material GF3. In particular, in Experimental Examples 1 to 16, the structural formulas of the third functional material GF3 are respectively as shown in structural formulas (GF3-9), (GF3-1), (GF3-2), (GF3-3), (GF3-4), (GF3-5), (GF3-6), (GF3-7), (GF3-10), (GF3-8), (GF3-11), (GF3-12), (GF3-25), (GF3-27), (GF3-28) and (GF3-29). In Comparative Example 1, the structural formula of the third functional material GF3 is as shown in the structural formula (GF3-9). In Comparative Example 2, the structural formulas of the material of the first hole transport layer 1332a and the material of the second hole transport layer 1332b are as shown in the structural formula (NPB).

In Experimental Examples 1 to 16 and Comparative Example 1, the material of the first electron blocking layer 1333a and the material of the second electron blocking layer 1333b are both the second functional material GF2. In particular, in Experimental Examples 1 to 16, the structural formulas of the second functional material GF2 are respectively as shown in structural formulas (GF2-9), (GF2-10), (GF2-11), (GF2-12), (GF2-13), (GF2-14), (GF2-15), (GF2-16), (GF2-17), (GF2-19), (GF2-18), (GF2-20), (GF2-21), (GF2-22), (GF2-23) and (GF2-24). In Comparative Example 1, the structural formula of the second functional material GF2 is as shown in the structural formula (GF2-1). In Comparative Example 2, the structural formulas of the material of the first electron blocking layer 1333a and the material of the second electron blocking layer 1333b are as shown in the structural formula (EBM-1).

In Experimental Examples 1 to 16, the material of the first auxiliary functional layer 1334a and the material of the second auxiliary functional layer 1334b are both the first functional material GF1. In particular, in Experimental Examples 1 to 16, the structural formulas of the first functional material GF1 are respectively as shown in structural formulas (GF1-3), (GF1-3), (GF1-4), (GF1-4), (GF1-7), (GF1-7), (GF1-8), (GF1-8), (GF1-9), (GF1-9), (GF1-10), (GF1-10), (GF1-27), (GF1-27), (GF1-29) and (GF1-29). In Comparative Example 1, the structural formulas of the material of the first auxiliary functional layer 1334a and the material of the second auxiliary functional layer 1334b are as shown in the structural formula (GF2-1). In Comparative Example 2, the structural formulas of the material of the first auxiliary functional layer 1334a and the material of the second auxiliary functional layer 1334b are as shown in the structural formula (EBM-1). Moreover, in Comparative Examples 1 and 2, the first electron blocking layer 1333a and the first auxiliary functional layer 1334a are combined into one film layer, and the second electron blocking layer 1333b and the second auxiliary functional layer 1334b are combined into one film layer.

In order to more clearly describe the differences in structure between the materials used in the film layers of the light-emitting devices 10 in the experimental examples and the comparative examples, the following Table 2 and Table 3 are used to more clearly show the structures of the materials used in the film layers of the light-emitting devices 10 in the experimental examples and the comparative examples.

TABLE 2

| | Anode | HIL1 | HTL1 | EBL1 | FGL1 | EML1 | HBL1 | N-CGL |
|---|---|---|---|---|---|---|---|---|
| Experimental | ITO | GF3-9/PD | GF3-9 | GF2-9 | GF1-3 | GH-1/ | HBL-1 | ETL- |
| Example 1 | | | | | | GH-1/ | | 1/Yb |
| Experimental | | GF3-1/PD | GF3-1 | GF2-10 | GF1-3 | GD-1 | | |
| Example 2 | | | | | | | | |
| Experimental | | GF3-2/PD | GF3-2 | GF2-11 | GF1-4 | | | |
| Example 3 | | | | | | | | |
| Experimental | | GF3-3/PD | GF3-3 | GF2-12 | GF1-4 | | | |
| Example 4 | | | | | | | | |
| Experimental | | GF3-4/PD | GF3-4 | GF2-13 | GF1-7 | | | |
| Example 5 | | | | | | | | |
| Experimental | | GF3-5/PD | GF3-5 | GF2-14 | GF1-7 | | | |
| Example 6 | | | | | | | | |
| Experimental | | GF3-6/PD | GF3-6 | GF2-15 | GF1-8 | | | |
| Example 7 | | | | | | | | |
| Experimental | | GF3-7/PD | GF3-7 | GF2-16 | GF1-8 | | | |
| Example 8 | | | | | | | | |
| Experimental | | GF3-10/PD | GF3-10 | GF2-17 | GF1-9 | | | |
| Example 9 | | | | | | | | |
| Experimental | | GF3-8/PD | GF3-8 | GF2-19 | GF1-9 | | | |
| Example 10 | | | | | | | | |
| Experimental | | GF3-11/PD | GF3-11 | GF2-18 | GF1-10 | | | |
| Example 11 | | | | | | | | |
| Experimental | | GF3-12/PD | GF3-12 | GF2-20 | GF1-10 | | | |
| Example 12 | | | | | | | | |
| Experimental | | GF3-25/PD | GF3-25 | GF2-21 | GF1-27 | | | |
| Example 13 | | | | | | | | |
| Experimental | | GF3-27/PD | GF3-27 | GF2-22 | GF1-27 | | | |
| Example 14 | | | | | | | | |
| Experimental | | GF3-28/PD | GF3-28 | GF2-23 | GF1-29 | | | |
| Example 15 | | | | | | | | |
| Experimental | | GF3-29/PD | GF3-29 | GF2-24 | GF1-29 | | | |
| Example 16 | | | | | | | | |

| | | | |
|---|---|---|---|
| Comparative | GF3-9/PD | GF3-9 | GF2-1 |
| Example 1 | | | |
| Comparative | NPB/PD | NPB | EBM-1 |
| Example 2 | | | |

TABLE 3

| | P-CGL | HTL2 | EBL2 | FGL2 | EML2 | HBL2 | ETL2 | EIL2 | |
|---|---|---|---|---|---|---|---|---|---|
| Experimental | GF3-9/PD | GF3-9 | GF2-9 | GF1-3 | GH-1/ | HBL-1 | ETL- | Yb | Mg/Ag |
| Example 1 | | | | | GH-1/ | | 1/Yb | | |
| Experimental | GF3-1/PD | GF3-1 | GF2-10 | GF1-3 | GD-1 | | | | |
| Example 2 | | | | | | | | | |
| Experimental | GF3-2/PD | GF3-2 | GF2-11 | GF1-4 | | | | | |
| Example 3 | | | | | | | | | |
| Experimental | GF3-3/PD | GF3-3 | GF2-12 | GF1-4 | | | | | |
| Example 4 | | | | | | | | | |
| Experimental | GF3-4/PD | GF3-4 | GF2-13 | GF1-7 | | | | | |
| Example 5 | | | | | | | | | |
| Experimental | GF3-5/PD | GF3-5 | GF2-14 | GF1-7 | | | | | |
| Example 6 | | | | | | | | | |
| Experimental | GF3-6/PD | GF3-6 | GF2-15 | GF1-8 | | | | | |
| Example 7 | | | | | | | | | |
| Experimental | GF3-7/PD | GF3-7 | GF2-16 | GF1-8 | | | | | |
| Example 8 | | | | | | | | | |
| Experimental | GF3-10/PD | GF3-10 | GF2-17 | GF1-9 | | | | | |
| Example 9 | | | | | | | | | |
| Experimental | GF3-8/PD | GF3-8 | GF2-19 | GF1-9 | | | | | |
| Example 10 | | | | | | | | | |
| Experimental | GF3-11/PD | GF3-11 | GF2-18 | GF1-10 | | | | | |
| Example 11 | | | | | | | | | |
| Experimental | GF3-12/PD | GF3-12 | GF2-20 | GF1-10 | | | | | |
| Example 12 | | | | | | | | | |
| Experimental | GF3-25/PD | GF3-25 | GF2-21 | GF1-27 | | | | | |
| Example 13 | | | | | | | | | |
| Experimental | GF3-27/PD | GF3-27 | GF2-22 | GF1-27 | | | | | |
| Example 14 | | | | | | | | | |
| Experimental | GF3-28/PD | GF3-28 | GF2-23 | GF1-29 | | | | | |
| Example 15 | | | | | | | | | |
| Experimental | GF3-29/PD | GF3-29 | GF2-24 | GF1-29 | | | | | |
| Example 16 | | | | | | | | | |

| | | | |
|---|---|---|---|
| Comparative | GF3-9/PD | GF3-9 | GF2-1 |
| Example 1 | | | |
| Comparative | NPB/PD | NPB | EBM-1 |
| Example 2 | | | |

It will be noted that, in Table 2, HIL1 represents the first hole injection layer 1331a, HTL1 represents the first hole transport layer 1332a, EBL1 represents the first electron blocking layer 1333a, FGL1 represents the first auxiliary functional layer 1334a, EML1 represents the light-emitting layer 131a of the first light-emitting unit 13a, HBL1 represents the first hole blocking layer 1323a, and N-CGL represents the electron generating layer 141; in Table 3, P-CGL represents the hole generating layer 142, HTL2 represents the second hole transport layer 1332b, EBL2 represents the second electron blocking layer 1333b, FGL2 represents the second auxiliary functional layer 1334b, EML2 represents the light-emitting layer 131b of the second light-emitting unit 13b, HBL2 represents the second hole blocking layer 1323b, ETL2 represents the second electron transport layer 1322b, and EIL2 represents the second electron injection layer 1321b. The mark “A/B” in Table 2 and Table 3 means that the material of the film layer includes a material A and a material B. For example, a material of P-CGL in Experimental Example 1 is GF3-1/PD, which means that the material of the hole generating layer 142 includes a third functional material GF3 of a structure represented by the structural formula (GF3-1) and a material of a structure represented by the structural formula (PD). The mark “A-x” in Table 2 and Table 3 means that the corresponding structural formula is A-x. For example, the content of the sub-grid corresponding to HTL2 in Experimental Example 2 is “GF3-1”, which means that the material of the second hole transport layer 1332b in Experimental Example 2 is a third functional material GF3 of a structure represented by the structural formula (GF3-1). As for the structural formulas represented by GF1-x, GF2-x, GF3-x (x is a positive integer), GH-1, GH-2, GD-1, NPB, PD, EBM-1, HBL-1 and ETL-1, reference is made to the above content, and details will not be repeated here.

Based on the above materials, the voltages (V), light emission efficiency (Eff.) and device life (LT) of the light-emitting devices 10 in Experimental Examples 1 to 16 and Comparative Examples 1 to 2 are tested. The data results of voltage (V), light emission efficiency (Eff.) and device life (LT) are based on that of Comparative Example 2, and the test results are as shown in the following Table 4.

TABLE 4

| | V(%) | Eff.(%) | LT(%) |
|---|---|---|---|
| Experimental Example 1 | 95.4 | 116.4 | 153.4 |
| Experimental Example 2 | 96.5 | 115.4 | 160.9 |
| Experimental Example 3 | 96.4 | 118.5 | 162.0 |
| Experimental Example 4 | 96.7 | 119.5 | 159.8 |
| Experimental Example 5 | 97.4 | 116.4 | 157.7 |
| Experimental Example 6 | 96.5 | 117.4 | 158.8 |
| Experimental Example 7 | 98.6 | 118.5 | 168.5 |
| Experimental Example 8 | 95.8 | 119.5 | 164.2 |
| Experimental Example 9 | 97.6 | 117.4 | 153.4 |
| Experimental Example 10 | 97.8 | 116.4 | 152.3 |
| Experimental Example 11 | 96.8 | 121.5 | 158.8 |
| Experimental Example 12 | 97.3 | 122.6 | 160.9 |
| Experimental Example 13 | 96.5 | 124.6 | 178.2 |
| Experimental Example 14 | 96.7 | 122.6 | 178.2 |
| Experimental Example 15 | 97.3 | 123.6 | 177.1 |
| Experimental Example 16 | 95.8 | 128.8 | 181.4 |
| Comparative Example 1 | 99 | 103 | 118 |
| Comparative Example 2 | 100 | 100 | 100 |

It can be seen from Table 4 that, the test data of Comparative Example 2 serves as a reference, and the voltages of the light-emitting devices in Experimental Examples 1 to 16 are in a range of 95.4% to 98.6%, which are lower than the voltages of the light-emitting devices in Comparative Examples 1 and 2. Thus, it can be seen that the voltages of the light-emitting devices in Experimental Examples 1 to 16 are relatively low, which may reduce the power consumption of the light-emitting device 10. The light emission efficiency of the light-emitting devices in Experimental Examples 1 to 16 is in a range of 115.4% to 128.8%, which is greater than the light emission efficiency of the light-emitting devices in Comparative Examples 1 and 2. Thus, it can be seen that the light emission efficiency of the light-emitting devices in Experimental Examples 1 to 16 is significantly improved. The device life of the light-emitting devices in Experimental Examples 1 to 16 is in a range of 152.3% to 181.4%, which is longer than the device life of the light-emitting devices in Comparative Examples 1 and 2. Thus, it can be seen that the device life of the light-emitting devices in Experimental Examples 1 to 16 is significantly prolonged.

In comparison with Comparative Example 2, in Comparative Example 1, the voltage of the light-emitting device is reduced, the light emission efficiency of the light-emitting device is improved, and the device life of the light-emitting device is prolonged. This is because in Comparative Example 1, the third functional material GF3 is used as the materials of the first hole transport layer 1332a and the second hole transport layer 1332b, and the second functional material GF2 is used as the materials of the first electron blocking layer 1333a and the second electron blocking layer 1333b; in an aspect, the second functional material GF2 and the third functional material GF3 have matching energy levels and migration rates, which may reduce the voltage, improve the light emission efficiency and prolong the device life; in another aspect, the second functional material GF2 has relatively high stability and relatively low refractive index, which may improve the light emission efficiency and prolong the device life.

Therefore, it can be seen from the above tests that, in the light-emitting device 10 provided in some embodiments of the present disclosure, the auxiliary functional layer 1334 containing the first functional material GF1, the electron blocking layer 1333 containing the second functional material GF2 and the hole transport layer 1332 containing the third functional material GF3 are included, and the first functional material GF1, the second functional material GF2 and the third functional material GF3 have matching energy levels and matching migration rates. Thus, it is possible to achieve effective injection and fast transport of holes, so that the stability of the first-type functional layer 133 is effectively improved, the device life is effectively prolonged, and the light emission efficiency is effectively improved. Furthermore, the driving voltage of the light-emitting device 10 may be reduced to reduce the power consumption of the light-emitting device 10. Based on the above, with the use of deuterated first functional material GF1, deuterated second functional material GF2 and deuterated third functional material GF3, the device life of the light-emitting device 10 may be further prolonged, and the light emission efficiency of the light-emitting device 10 may be further improved.

A lateral current of a device under test 30 including electrodes Q/a first-type functional layer 133 is tested. The test conditions of the following three devices under test 30 are the same.

The structure of the device under test 30 is shown in FIG. 9. For example, a manufacturing method of the above device under test 30 including the electrodes Q/first-type functional layer 133 is as described below: a patterned electrode layer is formed on a backplane using a material (e.g., indium tin oxide (ITO)) of the electrode Q, and a hole injection layer 1331, a hole transport layer 1332, an electron blocking layer 1333, and an auxiliary functional layer 1334 are sequentially formed in an opening of the electrode layer using a material of the hole injection layer 1331, a material of the hole transport layer 1332, a material of the electron blocking layer 1333, and a material of the auxiliary functional layer 1334. The process for forming the electrode layer is, for example, an etching process; the process for forming the hole injection layer 1331, the hole transport layer 1332, the electron blocking layer 1333, and the auxiliary functional layer 1334 is, for example, an evaporation process. After the manufacturing, portions of the electrode layer located on two sides of the first-type functional layer 133 form two electrodes Q respectively, and the two electrodes Q are electrically connected through the first-type functional layer 133 located therebetween.

It will be noted that, the materials of the electrodes Q of three devices under test 30 are the same, and all of them are indium tin oxide. The differences in the materials of the film layers of the three devices under test 30 will be described below.

Materials of hole injection layers 1331 of a device under test 301, a device under test 302 and a device under test 303 all include a hole transport material and a P-type dopant, and a mass ratio of the hole transport material to the P-type dopant is 98:2. In the device under test 301, the device under test 302 and the device under test 303, the structural formulas of the hole transport materials are respectively as shown in structural formulas (GF3-9), (GF3-10), and (NPB).

Materials of hole transport layers 1332 of the device under test 301 and the device under test 302 are both the third functional materials GF3. In particular, in the device under test 301 and the device under test 302, the structural formulas of the third functional materials GF3 are respectively as shown in structural formulas (GF3-9) and (GF3-10); in the device under test 303, the structural formula of the material of the hole transport layer 1332 is as shown in the structural formula (NPB).

Materials of electron blocking layers 1333 of the device under test 301 and the device under test 302 are both the second functional materials GF2. In particular, in the device under test 301 and the device under test 302, the structural formulas of the second functional materials GF2 are respectively as shown in structural formulas (GF2-9) and (GF2-17); in the device under test 303, the structural formula of the material of the electron blocking layer 1333 is as shown in the structural formula (EBM-1).

Materials of auxiliary functional layers 1334 of the device under test 301 and the device under test 302 are both the first functional materials GF1. In particular, in the device under test 301 and the device under test 302, the structural formulas of the first functional materials GF1 are respectively as shown in structural formulas (GF1-3) and (GF1-9); in the device under test 303, the structural formula of the material of the auxiliary functional layer 1334 is as shown in the structural formula (EBM-1). Moreover, in the device under test 303, the electron blocking layer 1333 and the auxiliary functional layer 1334 are combined into one film layer.

In order to more clearly describe the differences in structure between the materials used in the film layers of the three devices under test 30, the following Table 5 is used to more clearly show the structures of the materials used in the film layers of the three devices under test 30. In addition, the following Table 5 also shows the test results of the lateral current of the three devices under test 30. The data results of the lateral current are based on that of the device under test 303.

TABLE 5

| | Hole | Hole | Electron | Auxiliary | |
|---|---|---|---|---|---|
| | injection | transport | blocking | functional | Lateral |
| | layer | layer | layer | layer | current |
| Device under | GF3-9/PD | GF3-9 | GF2-9 | GF1-3 | 35% |
| test 301 | | | | | |
| Device under | GF3-10/PD | GF3-10 | GF2-17 | GF1-9 | 30% |
| test 302 | | | | | |
| Device under | NPB/PD | NPB | EBM-1 | | 100% |
| test 303 | | | | | |

It can be seen from Table 5 that, the test data of the device under test 303 is used as a reference; in a case where a circuit connecting the two electrodes Q is closed, the lateral currents of the device under test 301 and device under test 302 are respectively 35% and 30%, which are smaller than the lateral current of the device under test 303. Thus, it can be seen that with the provision of the auxiliary functional layer 1334 containing the first functional material GF1, the electron blocking layer 1333 containing the second functional material GF2 and the hole transport layer 1332 containing the third functional material GF3, the lateral current may be reduced, which avoids the color cross-talk due to the lateral current leakage between the blue light-emitting device 103 and the green light-emitting device 102, thereby improving the display effect of the OLED display panel 100.

Therefore, it can be seen from the above tests that, in the light-emitting device 10 provided in some embodiments of the present disclosure, with the provision of the auxiliary functional layer 1334 containing the first functional material GF1, the electron blocking layer 1333 containing the second functional material GF2 and the hole transport layer 1332 containing the third functional material GF3, the device life may be effectively prolonged and the light emission efficiency may be effectively improved, and the driving voltage of the light-emitting device 10 may be effectively reduced; in addition, the lateral current may be reduced to avoid color cross-talk, so that the display effect is improved.

The above are merely specific embodiments of the present disclosure, but the protection scope of the present disclosure is not limited thereto, and variations or substitutions that any person skilled in the art may conceive of within the technical scope of the present disclosure should all fall within the protection scope of the present disclosure. Therefore, the protection scope of the present disclosure should be subjected to the protection scope of the claims.

1. A light-emitting device, comprising: a cathode and an anode that are oppositely arranged, and at least two light-emitting units disposed between the cathode and the anode, wherein the at least two light-emitting units are arranged in sequence;
at least one light-emitting unit of the at least two light-emitting units includes: a light-emitting layer and a first-type functional layer disposed on a side of the light-emitting layer; the first-type functional layer includes an auxiliary functional layer, a material of the auxiliary functional layer includes a first functional material, and the first functional material is selected from any one of structures represented by a following general formula (I); 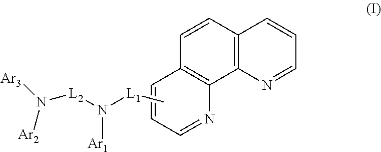
wherein L₁ is selected from any one of single bond, substituted or unsubstituted C6-C39 arylene, and substituted or unsubstituted C6-C39 heteroarylene,
L₂ is selected from any one of substituted or unsubstituted C6-C39 arylene and substituted or unsubstituted C6-C39 heteroarylene, and
Ar₁, Ar₂ and Ar₃ are same or different and are independently selected from any one of substituted or unsubstituted C6-C39 aryl, substituted or unsubstituted C5-C60 heteroaryl, substituted or unsubstituted C6-C60 aryloxy, substituted or unsubstituted C6-C39 arylamine, substituted or unsubstituted C6-C39 arylboryl, substituted or unsubstituted C6-C39 arylphosphino, and substituted or unsubstituted C6-C39 arylsilyl.

2. The light-emitting device according to claim 1, wherein the first-type functional layer is located on a side of the light-emitting layer proximate to the anode; and the auxiliary functional layer is configured to block electrons.

3. The light-emitting device according to claim 1, wherein the first-type functional layer further includes an electron blocking layer stacked with the auxiliary functional layer, a material of the electron blocking layer includes a second functional material, and the second functional material is selected from any one of structures represented by a following general formula (II); 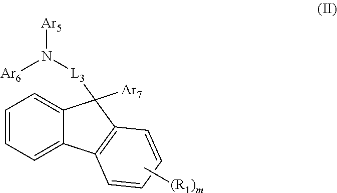
wherein L₃ is selected from any one of single bond, substituted or unsubstituted C3-C30 arylene, and substituted or unsubstituted C3-C30 heteroarylene,
Ar₅ and Ar₆ are same or different and are independently selected from any one of substituted or unsubstituted C6-C39 aryl, substituted or unsubstituted C5-C60 heteroaryl, substituted or unsubstituted C6-C60 aryloxy, substituted or unsubstituted C6-C39 arylamine, substituted or unsubstituted C6-C39 arylboryl, substituted or unsubstituted C6-C39 arylphosphino, and substituted or unsubstituted C6-C39 arylsilyl,
Ar₇ and R₁ are same or different and are independently selected from any one of hydrogen, deuterium, substituted or unsubstituted C1-C39 alkyl, substituted or unsubstituted C2-C39 alkenyl, substituted or unsubstituted C2-C39 alkynyl, substituted or unsubstituted C6-C39 aryl, substituted or unsubstituted C5-C60 heteroaryl, substituted or unsubstituted C6-C60 aryloxy, substituted or unsubstituted C1-C39 alkoxy, substituted or unsubstituted C6-C39 arylamine, substituted or unsubstituted C3-C39 cycloalkyl, substituted or unsubstituted C3-C39 heterocycloalkyl, substituted or unsubstituted C1-C39 alkylsilyl, substituted or unsubstituted C1-C39 alkylboryl, substituted or unsubstituted C6-C39 arylboryl, substituted or unsubstituted C6-C39 arylphosphino, and substituted or unsubstituted C6-C39 arylsilyl, and
m is a positive integer greater than or equal to 1.

4. The light-emitting device according to claim 3, wherein the electron blocking layer is located on a side of the auxiliary functional layer away from the light-emitting layer and configured to block electrons.

5. The light-emitting device according to claim 3, wherein the first-type functional layer further includes a hole transport layer stacked with the electron blocking layer, a material of the hole transport layer includes a third functional material, and the third functional material is selected from any one of structures represented by a following general formula (III); 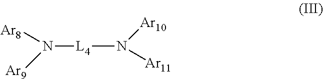
wherein L₄ is selected from any one of substituted or unsubstituted C3-C30 arylene, and substituted or unsubstituted C3-C30 heteroarylene, and
Ar₈, Ar₉, Ar₁₀ and Ar₁₁ are same or different and are independently selected from any one of substituted or unsubstituted C6-C39 aryl, substituted or unsubstituted C5-C60 heteroaryl, substituted or unsubstituted C6-C60 aryloxy, substituted or unsubstituted C1-C39 alkoxy, substituted or unsubstituted C6-C39 arylamine, and substituted or unsubstituted C6-C39 arylsilyl.

6. The light-emitting device according to claim 5, wherein the hole transport layer is located on a side of the electron blocking layer away from the light-emitting layer and configured to transport holes.

7. The light-emitting device according to claim 1, wherein the first functional material is selected from any one of structures represented by a following general formula (IV); 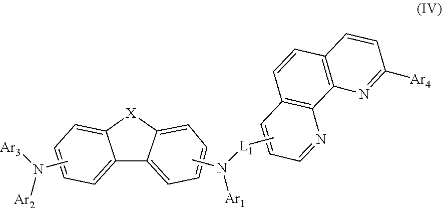
wherein X is selected from any one of O, S, N(R₂), and C(R₃R₄), and
R₂, R₃, R₄ and Ar₄ are same or different and are independently selected from any one of hydrogen, deuterium, substituted or unsubstituted C1-C39 alkyl, substituted or unsubstituted C2-C39 alkenyl, substituted or unsubstituted C2-C39 alkynyl, substituted or unsubstituted C6-C39 aryl, substituted or unsubstituted C5-C60 heteroaryl, substituted or unsubstituted C6-C60 aryloxy, substituted or unsubstituted C1-C39 alkoxy, substituted or unsubstituted C6-C39 arylamine, substituted or unsubstituted C3-C39 cycloalkyl, substituted or unsubstituted C3-C39 heterocycloalkyl, substituted or unsubstituted C1-C39 alkylsilyl, substituted or unsubstituted C1-C39 alkylboryl, substituted or unsubstituted C6-C39 arylboryl, substituted or unsubstituted C6-C39 arylphosphino, and substituted or unsubstituted C6-C39 arylsilyl.

8. The light-emitting device according to claim 7, wherein in a case where the first functional material is selected from the structures represented by the general formula (I), the structures represented by the general formula (I) each contains at least one deuterium atom; or
in a case where the first functional material is selected from structures represented by the general formula (IV), the structures represented by the general formula (IV) each contains at least one deuterium atom.

9. The light-emitting device according to claim 3, wherein at least one of Ar₅, Ar₆, Ar₇, L₃, and R₁ contains a deuterium atom.

10. The light-emitting device according to claim 5, wherein at least one of Ar₅, Ar₉, Ar₁₀, Ar₁₁, and L₄ contains a deuterium atom.

11. The light-emitting device according to claim 5, wherein at least one of Ar₈, Ar₉, Ar₁₀ and Ar₁₁ is different from son a rest of Ar₈, Ar₉, Ar₁₀ and Ar₁₁.

12. The light-emitting device according to claim 5, wherein a first ionization potential of the first functional material is greater than or equal to a first ionization potential of the second functional material, and the first ionization potential of the second functional material is greater than or equal to a first ionization potential of the third functional material.

13. The light-emitting device according to claim 12, wherein a difference between the first ionization potential of the first functional material and the first ionization potential of the second functional material is less than or equal to 0.2 eV; and/or
a difference between the first ionization potential of the second functional material and the first ionization potential of the third functional material is less than or equal to 0.2 eV; and/or
a difference between the first ionization potential of the first functional material and the first ionization potential of the third functional material is less than or equal to 0.3 ev.

14. (canceled)

15. (canceled)

16. The light-emitting device according to claim 3, wherein a thickness of the electron blocking layer is greater than a thickness of the auxiliary functional layer.

17-19. (canceled)

20. The light-emitting device according to claim 5, wherein the light-emitting device further comprises a charge generating layer located between two adjacent light-emitting units of the at least two light-emitting units; the charge generating layer includes an electron generating layer and a hole generating layer that are stacked; and
a material of the hole generating layer includes the third functional material.

21. The light-emitting device according to claim 5, wherein the first-type functional layer further includes a hole injection layer, and the hole injection layer is located on a side of the hole transport layer away from the electron blocking layer; and
a material of the hole injection layer includes the third functional material.

22. The light-emitting device according to claim 1, wherein the at least one emitting unit further includes a second-type functional layer, and the second-type functional layer is located on a side of the light-emitting layer away from the first-type functional layer and configured to transport electrons.

23. The light-emitting device according to claim 1, wherein a light-emitting layer of each light-emitting unit of the at least two light-emitting units is configured to emit green light.

24. A display panel, comprising a plurality of light-emitting devices each according to claim 1, and
driving circuits configured to drive the light-emitting devices to emit light.

25. A display apparatus, comprising: the display panel according to claim 24, and
a driver chip configured to drive the display panel to display images.
